(19) United States
(12) Patent Application Publication
(10) Pub. No.: US 2011/0156109 A1
(43) Pub. Date: Jun. 30, 2011

(54) METHOD AND SYSTEM FOR MANIPULATING ORGANIC NANOSTRUCTURES

(75) Inventors: Ehud GAZIT, Ramat-HaSharon (IL); Lihi Adler-Abramovich, Rishon-LeZion (IL); Jaime Alberto Castillo Leon, Lund (SE); Maria Ioannou Dimaki, Albertslund (DK); Winnie Edith Svendsen, Copenhagen S. (DK); Emmanouil Kasotakis, Heraklion (GR); Anna Mitraki, Heraklion (GR)

(73) Assignees: Ramot at Tel-Aviv University Ltd., Tel-Aviv (IL); Technical University of Denmark (DTU), Kongens Lyngby (DK); The University of Crete, Heraklion (GR)

(21) Appl. No.: 12/979,406

(22) Filed: Dec. 28, 2010

Related U.S. Application Data
(60) Provisional application No. 61/282,190, filed on Dec. 28, 2009.

(51) Int. Cl. H01L 29/772; C25B 9/00

(52) U.S. Cl. 257/288; 204/450; 204/547; 977/700; 257/E29.242

(57) ABSTRACT

A method of manipulating an organic nanostructure is disclosed. The method comprises: contacting a liquid sample having the organic nanostructure therein with an arrangement of electrodes, and applying voltage to the arrangement of electrodes to manipulate and immobilize the organic nanostructure over the electrodes by electrokinetics.

### RELATED APPLICATION

This application claims the benefit of priority from U.S. Provisional Patent Application No. 61/282,190 filed on Dec. 28, 2009, the contents of which are incorporated by reference as if fully set forth herein.

### FIELD AND BACKGROUND OF THE INVENTION

The present invention, in some embodiments thereof, relates to nanotechnology and, more particularly, but not exclusively, to a method and system for manipulating organic nanostructures.

It is well established that future development of devices such as microelectronics devices and chemical sensors will be achieved by increasing the packing density of device components. Traditionally, microscopic devices have been formed from larger objects, but as these products get smaller, below the micron level, this process becomes increasingly difficult. It is therefore appreciated that the opposite approach is to be employed, essentially, the building of microscopic devices via objects of nanometric dimensions.

In particular, nanostructures of elongated shape have attracted extensive interest due to their great potential for addressing some basic issues about dimensionality and space confined transport phenomena as well as related applications.

Numerous configurations have been proposed and applied for the construction of nanostructures. Most widely used are the fullerene carbon nanotubes. Two major forms of carbon nanotubes exist, single-walled nanotubes (SWNT), which can be considered as long wrapped graphene sheets and multi walled nanotubes (MWNT) which can be considered as a collection of concentric SWNTs with different diameters.

Other well-studied nanostructures are lipid surfactant nanomaterials (e.g., diacetylene lipids) which self-assemble into well-ordered nanotubes and other bilayer assemblies in water and aqueous solution [Yager (1984) Mol. Cryst. Liq. Cryst. 106:371-381; Schnur (1993) Science 262:1669-1676; Selinger (2001) J. Phys. Chem. B 105:7157-7169]. One proposed application of lipid tubules is as vehicles for controlled drug release. Accordingly, such tubes coated with metallic copper and loaded with antibiotics were used to prevent marine fouling.

Peptide building blocks have also been shown to form nanotubes. Peptide-based nanotubular structures have been made through stacking of cyclic D-, L-peptide subunits. These peptides self-assemble through hydrogen-bonding interactions into nanotubules, which in-turn self-assemble into ordered parallel arrays of nanotubes. The number of amino acids in the ring determines the inside diameter of the nanotubes obtained. Such nanotubes have been shown to form transmembrane channels capable of transporting ions and small molecules [Ghadiri, M. R. et al., Nature 366, 324-327 (1993); Ghadiri, M. R. et al., Nature 369, 301-304 (1994); Bong, D. T. et al., Angew. Chem. Int. Ed. 40, 988-1011 (2001)].

Peptide nanostructures and various applications thereof are described in International Patent Application, Publication Nos. WO2004/052773, WO2004/060791, WO2005/000589, WO2006/027780 and WO2006/013552, all being incorporated by reference by their entirety.

Generally, peptide nanostructures can posses many ultrastructural and physical similarities to carbon nanotubes. Known peptide nanostructures are made by self assembly of aromatic dipeptides, such as diphenylalanine. The assembled dipeptides form ordered assemblies of various structures with persistence length on the order of micrometers.

For industrial applications, self-assembled peptide nanostructures are favored over carbon nanotubes from standpoint of cost, production means and availability. Additionally, peptides nanostructures can be used as organic building blocks for bio-nanotechnology owing to their biocompatibility, chemical flexibility and versatility, biological recognition abilities and facile synthesis [Reches, M. and Gazit, E. Casting metal nanowires within discrete self-assembled peptide nanotubes. Science 300, 625-627 (2003).].

Peptide nanostructures have been proposed to be used in various technological applications, such as microelectronics, magnetic recording systems, chemical sensors, displays systems, memory media, electron-emission lithography and thermoelectric systems.

### SUMMARY OF THE INVENTION

According to an aspect of some embodiments of the present invention there is provided a method of manipulating an organic nanostructure. The method comprises: contacting a liquid sample having the organic nanostructure therein with an arrangement of electrodes; and applying voltage to the arrangement of electrodes to manipulate and immobilize the organic nanostructure over the electrodes by electrokinetics.

According to some embodiments of the invention the method further comprises removing the liquid following the manipulation.

According to some embodiments of the invention the removing the liquid comprises directing a stream of gas.

According to some embodiments of the invention the voltage is alternating voltage.

According to some embodiments of the invention the a characteristic frequency of the alternating voltage is from about 0.5 MHz to about 1.5 MHz.

According to some embodiments of the invention the applying the voltage is for a time period of at least 2 minutes.

According to some embodiments of the invention the voltage is selected such that the nanostructure is immobilized to bridge a gap between two electrodes.

According to some embodiments of the invention the liquid sample comprises a plurality of organic nanostructure therein, wherein a concentration of the organic nanostructures in the liquid is selected such that a single organic nanostructure is immobilized to bridge a gap between two electrodes.

According to some embodiments of the invention the liquid comprises a plurality of organic nanostructures therein, wherein a concentration of the organic nanostructures in the liquid is selected such that a bundle of organic nanostructures is immobilized to bridge a gap between two electrodes.

According to some embodiments of the invention the liquid comprises a plurality of organic nanostructures therein, wherein the arrangement of electrodes forms a printed circuit board having a plurality of inter-electrode gaps, and wherein the voltage is selected such that at least two different nanostructures are immobilized to bridge respective two gaps.

According to some embodiments of the invention the method further comprises cutting the printed circuit board to form at least two electronic devices each having at least two gapped electrodes and at least one immobilized nanostructure bridging the gap.

According to some embodiments of the invention the nanostructure is an elongated nanostructure.

According to some embodiments of the invention the nanostructure is a peptide nanostructure.

According to some embodiments of the invention the peptide nanostructure is selected from the group consisting of a peptide nanotube and a peptide nanowire.

15. The method of claim 1, the manipulation is by dieletrophoresis.

According to some embodiments of the invention the manipulation is by eletrophoresis.

According to an aspect of some embodiments of the present invention there is provided an electronic assembly, comprising a plurality of electronic devices formed on a single substrate, each electronic device having at least two gapped electrodes and at least one immobilized peptide nanostructure bridging the gap.

According to some embodiments of the invention the electronic devices are laterally separated and independently operative.

According to some embodiments of the invention the electronic devices are identical.

According to some embodiments of the invention at least one of the electronic devices is a field-effect transistor, wherein the gap is between a source electrode and a drain electrode of the field-effect transistor.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Some embodiments of the invention are herein described, by way of example only, with reference to the accompanying drawings and images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a flowchart diagram illustrating a method suitable for manipulating an organic nanostructure, according to various exemplary embodiments of the present invention.

FIG. 2 is a schematic illustration showing a representative example a pair of electrodes with a gap between the electrodes, according to some exemplary embodiments of the present invention.

FIG. 3 is a schematic illustration of an arrangement of electrodes which can be used according to some embodiments of the present invention for simultaneous manufacturing of a plurality of devices.

FIG. 4A is a schematic illustration of a process executed in experiments performed according to some embodiments of the present invention for the fabrication of a dielectrophoresis microchip.

FIG. 4B is an image showing a dielectrophoresis microchip prepared by the process illustrated in FIG. 4A.

FIG. 5A is a schematic molecular structure of a diphenylalanine peptide used in experiments performed according to some embodiments of the present invention.

FIG. 5B is a SEM image of diphenylalanine peptide nanotubes used in experiments performed according to some embodiments of the present invention. The Nanotube are shown on a silicon oxide surface.

FIG. 6 shows results of a simulation experiments performed according to some embodiments of the present invention.

FIGS. 7A-B are an AFM image (FIG. 7A) and a SEM image (FIG. 7B) of amyloid peptide nanotubes immobilized on Au electrodes using dielectrophoresis.

FIG. 8A is an AFM topography image of a peptide nanotube lying on a silicon oxide surface.

FIG. 8B is a graph resulting from a line scan along the grey line of FIG. 8A.

FIG. 9A is a phase image of a peptide nanotube lying on a silicon oxide surface.

FIG. 9B is a graph resulting from a line scan along the grey line of FIG. 9A.

FIG. 10 is an AFM image of a single amyloid peptide nanotube immobilized in experiments performed in accordance with some embodiments of the present invention. The peptide nanotube was manipulated by dielectrophoresis and was immobilized to bridge a gap between two electrodes.

FIG. 11A shows I-V curves obtained in experiments performed according to some embodiments of the present invention. Shown are I-V curves describing data acquired from three configurations: (i) amyloid peptide nanotube bundles bridging the gap between two microelectrodes (black line), (ii) a single amyloid peptide nanotube bridging the gap between two microelectrodes (red line), and (iii) a control experiment in which the gap remained empty.

FIG. 11B shows an I-V curve obtained in another experiment performed according to some embodiments of the present invention. Shown is I-V curves describing data acquired from a configuration in which a silver filled peptide nanotube was immobilized to bridge the gap between two microelectrodes.

FIG. 12 illustrates a EFM phase mode technique employed during experiments performed according to some exemplary embodiments of the present invention.

FIGS. 13A-D show a topography image of a diphenylalanine peptide nanotube (FIG. 13A), a lift phase image of a diphenylalanine peptide nanotube (FIG. 13B), a line profile of the images of FIGS. 13A and 13B (FIG. 13C), and a schematic illustration of the expected hollow structure of the nanotube as interpreted by the lift signal.

FIGS. 14A-D show a lift phase image of a silver filled peptide nanotube (FIG. 14A), a line profile of the image of FIG. 14A (FIG. 14B), a change in the lift phase as a function of the inverted scan rate (FIG. 14C), and mean lifetime of the different nanotube of their height (FIG. 14D).

FIGS. 15A-B show a lift phase image of a pure silver wire (FIG. 15A) and a line profile of the image of FIG. 15A (FIG. 15B).

FIG. 16A is a TEM image of eight-amino acid peptide NC nanofibers used in experiments performed according to some embodiments of the present invention.

FIG. 16B is a SEM image of eight-amino acid peptide CN nanofibers used in experiments performed according to some embodiments of the present invention.

FIGS. 17A-B show cyclic voltammetry of a CN nanofiber modified graphite electrode (FIG. 17A) and an unmodified graphite electrode (FIG. 17B), as measured in experiments performed according to some embodiments of the present invention.

FIGS. 18A-B show cyclic voltammetry of NS nanofibers with Au nanoparticles modified graphite electrode (FIG. 18A) and an unmodified graphite electrode (FIG. 18B), as measured in experiments performed according to some embodiments of the present invention.

FIGS. 19A-B show cyclic voltammetry of CS nanofibers with Au nanoparticles modified graphite electrode (FIG. 19A) and an unmodified graphite electrode (FIG. 17B), as measured in experiments performed according to some embodiments of the present invention.

### DESCRIPTION OF SPECIFIC EMBODIMENTS OF THE INVENTION

The present invention, in some embodiments thereof, relates to nanotechnology and, more particularly, but not exclusively, to a method and system for manipulating organic nanostructures.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

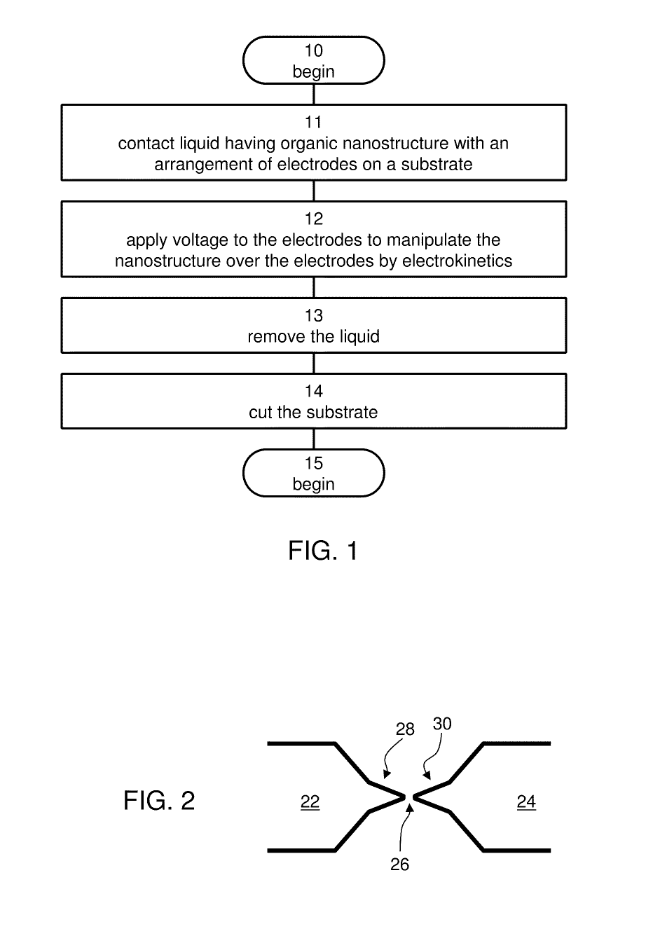

Referring now to the drawings, FIG. 1 is a flowchart diagram illustrating a method suitable for manipulating an organic nanostructure, according to various exemplary embodiments of the present invention. The method begins at 10 and continues to 11 at which a liquid sample having one or more organic nanostructures therein is contacted with an arrangement of electrodes.

At least some (e.g., 50% or more) of the organic nanostructures are optionally and preferably elongated nanostructure.

The term “organic nanostructure” refers to a nanostructure made at least in part of organic substance. As used herein, the phrase “organic substance” describes any substance that comprises carbon and hydrogen atoms, with or without additional elements.

The term “elongated nanostructure” generally refers to a three-dimensional body made of a solid substance, in which one of its dimensions is at least 2 times, or at least 10 times, or at least 50 times e.g., at least 100 times larger than any of the other two dimensions. The largest dimension of the elongated solid structure is referred to herein as the longitudinal dimension or the length of the nanostructure, and the other two dimensions are referred to herein as the transverse dimensions. The largest of the transverse dimensions is referred to herein as the diameter or width of the elongated nanostructure. The ratio between the length and the width of the nanostructure is known as the aspect ratio of the nanostructure.

In various exemplary embodiments of the invention the length of the elongated nanostructure is at least 100 nm, or at least 500 nm, or at least 1 μm, or at least 2 μm, or at least 3 μm, e.g., about 4 μm, or more. The width of the elongated nanostructure is preferably less than 1 μm. In various exemplary embodiments of the invention the width of the nanostructure is from about 5 nm to about 200 nm.

Representative examples of nanostructures suitable for the present embodiment are provided hereinunder.

The liquid sample can be delivered to the electrodes in any way known in the art, including, without limitation, dripping, spreading, dipping and the like. In some embodiments of the present invention a microfluidic system is employed for delivering the liquid sample in microchannels directly to the electrodes or a vicinity thereof.

The method according to some embodiments of the present invention continues to 12 at which voltage is applied to the electrodes to manipulate and immobilize the organic nanostructure(s) over the electrodes by electrokinetics.

Electrokinetics is the use of electrical fields (and the resulting forces) to manipulate matter in a fluid medium. Electrokinetics is a term which encompasses all types of processes in which the application of electric field results in motion of matter.

One type of electrokinetics is electrophoresis. Electrophoresis is particularly useful when the nanostructures are electrically charged. Electrophoresis is a phenomenon in which charged nanostructures, located between two electrically biased electrodes, are influenced by the electric field generated by the electrodes such that they are attracted to one electrode and repulsed by the other electrode. The attracting and repulsing forces are proportional to the nanostructure net charge and the electric field magnitude.

Another type of electrokinetics is dielectrophoresis. Dielectrophoresis is particularly useful when the nanostructures are electrically polarizable. Dielectrophoresis is the motion of matter caused by polarization effects in a nonuniform electric field. Electric fields induce dielectric polarization components in polarizable nanostructures. The extent of the nanostructure's polarization is related to its effective dielectric constant (polarizability) and to the electric field magnitude. Nanostructures that have high dielectric constants experience significant polarization while nanostructures that have low dielectric constants experience lower polarization. In dielectrophoresis, nanostructure motion is produced by the interaction between the nonuniform electric field and the dielectric polarization components induced in the nanostructure and in the surrounding fluid medium by the field. In a uniform field, neutral nanostructures, including neutral polarized nanostructures, experience no net electric force. However, when placed in a nonuniform field polarizable, nanostructures experience a net force in the direction of the field gradient, tending to move the nanostructures towards regions of higher electric field strength. This motion is known as positive dielectrophoresis. If the polarizability of the suspension medium exceeds that of the nanostructures, they tend to move towards regions of lower electric field strength. This motion is known as negative dielectrophoresis.

Dielectrophoretic forces suitable for the present embodiments are induced by classic dielectrophoresis or by traveling-wave dielectrophoresis (twDEP). Classic dielectrophoresis refers to motion arising from nonuniform distribution in the magnitude of a direct-current (DC) or alternating-current (AC) electric field. Traveling-wave dielectrophoresis refers to motion arising from nonuniform distribution in the phase of an alternating-current electric field.

The arrangement of electrodes over which the organic nanostructure is manipulated by electrokinetics can vary depending on the application for which the manipulation and immobilization is performed. Typically, the manipulation and immobilization is for the purpose of forming an electronic device e.g., an elementary device (such as, but not limited to a diode, a transistor, particularly a field-effect transistor, etc.) or a composite device such as, but not limited to, a sensor. In these embodiments, the electrodes are arranged according to the desired structure of the device.

For example, in some embodiments of the present invention the electrodes include a pair of electrode having a gap therebetween (e.g., a source electrode and a drain electrode). A representative example of such pair of electrodes is illustrated in FIG. 2, showing a first electrode 22 a second electrode 24 and a gap 26 between electrode 22 and electrode 24. At least one of electrodes 22 and 24 optionally and preferably comprises a tip, generally shown at 28 and 30. A tipped electrode has the advantage that it generates a nonuniform electric field, once biased.

The electrodes can be made of any electrically conductive material, preferably a metal such as, but not limited to, gold, silver, platinum, copper, nickel, titanium, aluminum and any combination thereof. The electrodes can be fabricated using any known microelectronic fabrication technique. The fabrication process can be a subtractive process, an additive process or a combined process which includes a combination of subtractive steps and additive steps. Thus, the fabrication process includes at least one of: photolithography, evaporation, deposition, etching (using either wet chemical processes or plasma processes), focused ion milling, and lift off. A representative example of process suitable for fabricating the electrodes is provided in the Examples section that follows.

The width of the inter-electrode gap, which is defined as the shortest distance between the electrodes, is preferably smaller than at least the largest dimension of the nanostructures so as to allow the nanostructures to bridge the gap once immobilized thereover. Preferably, the gap width is on a micoscale or sub-microscale. A gap size suitable for the present embodiments is from about 0.1 μm to about 10 μm, or from about 0.5 μm to about 2 μm, e.g., about 1 μm.

Optionally and preferably, the application of voltage is such that the nanostructure(s) is/are immobilized to bridge the inter-electrode gap. The voltage can be alternative voltage (also referred to as “AC voltage”) or direct voltage (also referred to as “DC voltage”), as desired. When an alternative voltage is employed, the characteristic frequency of the voltage is on a megahertz scale, e.g., from about 0.1 MHz to about 10 MHz, or from about 0.5 MHz to about 1.5 MHz, say, about 1 MHz. Other frequencies are not excluded from the scope of the present invention. The voltage can be applied for a time period of at least 2 minutes, more preferably from about 2 minutes to about 10 minutes, but other time periods are not excluded from the scope of the present invention.

The number of nanostructures that are immobilized on the electrodes can be controlled by judicious selection of the concentration of the organic nanostructures in the liquid. In some embodiments of the present invention the concentration is selected such that a single organic nanostructure is immobilized to bridge the inter-electrode gap, and in some embodiments the concentration is selected such that a bundle of organic nanostructures is immobilized to bridge the gap. In experiments performed by the present inventors, a concentration of about 2 mg/mL was used for immobilizing a bundle of organic nanostructures on a single gap, and a diluted concentration of about 0.5 mg/mL was used for immobilizing a single nanostructure on the gap. It is appreciated that different types of nanostructures may require different concentrations. One of ordinary skills in the art, provided with the details described herein would know how to select the concentration of the liquid sample for immobilizing the desired number of nanostructures on the electrodes.

The present embodiments can be employed for manufacturing a single device or a plurality of devices. When two or more devices are manufactured, they are optionally and preferably manufactured generally simultaneously.

As used herein, a plurality of devices are said to be manufactured “generally simultaneously” if the total manufacturing time of all the devices is shorter than the sum of manufacturing times of each individual device.

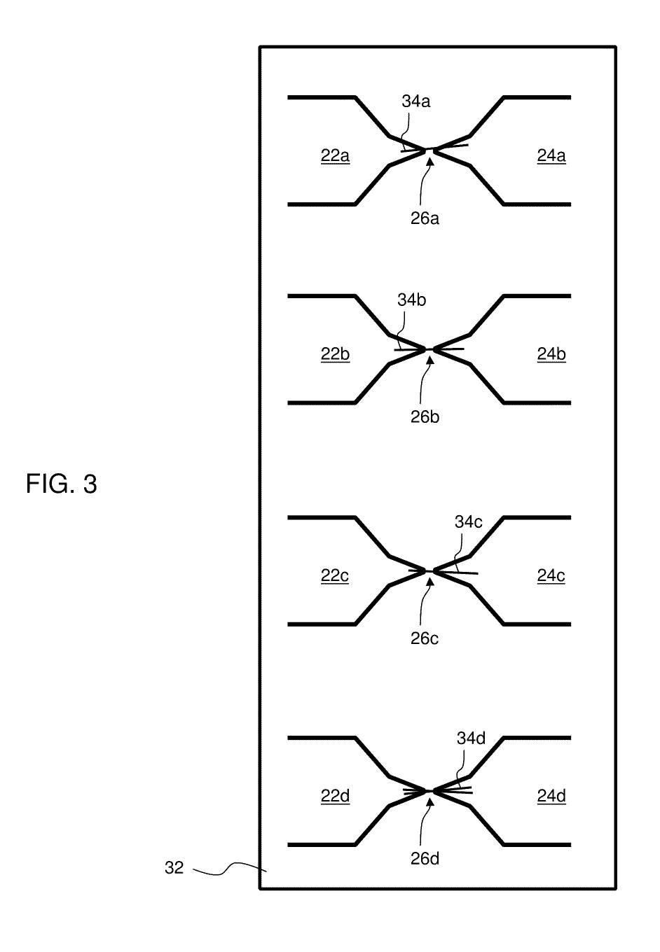

A preferred procedure for simultaneous manufacturing of a plurality of devices according to some embodiments of the present invention will now be explained with reference to FIG. 3. An arrangement of electrodes is prepared on a substrate to form a printed circuit board 32 having a plurality of inter-electrode gaps. FIG. 3 illustrates representative example of an arrangement which includes four pairs of electrodes. The electrodes in FIG. 3 are designated 22a through 22d and 24a through 24d, and they are arranged in a single column, but this need not necessarily be the case, since, for some applications, it may not be necessary to have the electrodes arranged in a column and/or to have particularly four pairs of electrodes. The inter-electrode gaps are designated 26a through 26d.

The liquid sample is placed on the circuitry and the voltage is applied to immobilize the nanostructures 34a-34d on the electrodes. In various exemplary embodiments of the invention at least two different nanostructures are immobilized to respectively bridge two different gaps. For example, nanostructure 34a bridges gap 26a, nanostructure 34b bridges gap 26b and so on. Optionally, but not necessarily, each gap is bridged by a single nanostructure. In some embodiments, at least one of the gap (e.g., gap 26d) is bridged by a bundle of nanostructures.

Referring again to FIG. 1, in some embodiments of the present invention the method continues to 13 at which the liquid is removed, following the manipulation. A preferred procedure for removing the liquid is by a stream of gas, e.g., nitrogen, but other liquid removal techniques are not excluded from the scope of the present invention.

When simultaneous manufacturing is employed, the method optionally and preferably continues to 14 at which the printed circuit board 32 is cut to form at least two electronic devices each having at least two gapped electrodes and at least one immobilized nanostructure bridging gap. Each such electronic devices can be a stand alone device, such as, but not limited to, a sensor, a transistor, a diode, a switch, and the like, or it can be thereafter incorporated or connected to circuitry for performing its designated function.

The method ends as 15.

The organic nanostructures of the present embodiments can be of any type known in the art. One example of an organic nanostructure suitable for the present embodiments is a peptide nanostructure.

The term “peptide” as used herein encompasses native peptides (either degradation products, synthetically synthesized peptides or recombinant peptides) and peptidomimetics (typically, synthetically synthesized peptides), as well as peptoids and semipeptoids which are peptide analogs, which may have, for example, modifications rendering the peptides more stable while in a body. Such modifications include, but are not limited to N terminus modification, C terminus modification, peptide bond modification, including, but not limited to, CH₂—NH, CH₂—S, CH₂—S═O, O═C—NH, CH₂—O, CH₂—CH₂, S═C—NH, CH═CH or CF═CH, backbone modifications, and residue modification. Methods for preparing peptidomimetic compounds are well known in the art and are specified, for example, in Quantitative Drug Design, C. A. Ramsden Gd., Chapter 17.2, F. Choplin Pergamon Press (1992), which is incorporated by reference as if fully set forth herein. Further details in this respect are provided hereinunder.

Peptide nanostructures suitable for the present embodiments are described in International Patent Application, Publication Nos. WO2004/052773, WO2004/060791, WO2005/000589, WO2006/027780 and WO2006/013552, the contents of which are hereby incorporated by reference by their entirety.

Peptide bonds (—CO—NH—) within the peptide of the present embodiments may be substituted, for example, by N-methylated bonds (—N(CH₃)—CO—), ester bonds (—C(R)H—C—O—O—C(R)—N—), ketomethylen bonds (—CO—CH₂—), α-aza bonds (—NH—N(R)—CO—), wherein R is any alkyl, e.g., methyl, carba bonds (—CH₂—NH—), hydroxyethylene bonds (—CH(OH)—CH₂—), thioamide bonds (—CS—NH—), olefinic double bonds (—CH═CH—), retro amide bonds (—NH—CO—), peptide derivatives (—N(R)—CH₂—CO—), wherein R is the “normal” side chain, naturally presented on the carbon atom.

These modifications can occur at any of the bonds along the peptide chain and even at several (2-3) at the same time.

The peptides forming the nanostructures of the present embodiments typically comprise from 2 to 15 amino acid residues. More preferably, the peptides are short peptides of less than 10 amino acid residues, more preferably less than 8 amino acid residues and more preferably are peptides of 2-6 amino acid residues, and hence each peptide preferably has 2, 3, 4, 5, or 6 amino acid residues.

As used herein the phrase “amino acid” or “amino acids” is understood to include the 20 naturally occurring amino acids; those amino acids often modified post-translationally in vivo, including, for example, hydroxyproline, phosphoserine and phosphothreonine; and other unusual amino acids including, but not limited to, 2-aminoadipic acid, hydroxylysine, isodesmosine, nor-valine, nor-leucine and ornithine. Furthermore, the term “amino acid” includes both D- and L-amino acids.

Tables 1 and 2 below list naturally occurring amino acids (Table 1) and non-conventional or modified amino acids (Table 2) which can be used with the present invention.

TABLE 1

| | Three-Letter | One-letter |
|---|---|---|
| Amino Acid | Abbreviation | Symbol |
| Alanine | Ala | A |
| Arginine | Arg | R |
| Asparagine | Asn | N |
| Aspartic acid | Asp | D |
| Cysteine | Cys | C |
| Glutamine | Gln | Q |
| Glutamic Acid | Glu | E |
| Glycine | Gly | G |
| Histidine | His | H |
| isoleucine | Iie | I |
| Leucine | Leu | L |
| Lysine | Lys | K |
| Methionine | Met | M |
| phenylalanine | Phe | F |
| Proline | Pro | P |
| Serine | Ser | S |
| Threonine | Thr | T |
| tryptophan | Trp | W |
| tyrosine | Tyr | Y |
| Valine | Val | V |
| Any amino acid as above | Xaa | X |

TABLE 2

| Non-conventional amino acid | Code | Non-conventional amino acid | Code |
|---|---|---|---|
| α-aminobutyric acid | Abu | L-N-methylalanine | Nmala |
| α-amino-α-methylbutyrate | Mgabu | L-N-methylarginine | Nmarg |
| aminocyclopropane- | Cpro | L-N-methylasparagine | Nmasn |
| carboxylate | | L-N-methylaspartic acid | Nmasp |
| aminoisobutyric acid | Aib | L-N-methylcysteine | Nmcys |
| aminonorbornyl- | Norb | L-N-methylglutamine | Nmgin |
| carboxylate | | L-N-methylglutamic acid | Nmglu |
| cyclohexylalanine | Chexa | L-N-methylhistidine | Nmhis |
| cyclopentylalanine | Cpen | L-N-methylisolleucine | Nmile |
| D-alanine | Dal | L-N-methylleucine | Nmleu |
| D-arginine | Darg | L-N-methyllysine | Nmlys |
| D-aspartic acid | Dasp | L-N-methylmethionine | Nmmet |
| D-cysteine | Dcys | L-N-methylnorleucine | Nmnle |
| D-glutamine | Dgln | L-N-methylnorvaline | Nmnva |
| D-glutamic acid | Dglu | L-N-methylornithine | Nmorn |
| D-histidine | Dhis | L-N-methylphenylalanine | Nmphe |
| D-isoleucine | Dile | L-N-methylproline | Nmpro |
| D-leucine | Dleu | L-N-methylserine | Nmser |
| D-lysine | Dlys | L-N-methylthreonine | Nmthr |
| D-methionine | Dmet | L-N-methyltryptophan | Nmtrp |
| D-ornithine | Dorn | L-N-methyltyrosine | Nmtyr |
| D-phenylalanine | Dphe | L-N-methylvaline | Nmval |
| D-proline | Dpro | L-N-methylethylglycine | Nmetg |
| D-serine | Dser | L-N-methyl-t-butylglycine | Nmtbug |
| D-threonine | Dthr | L-norleucine | Nle |
| D-tryptophan | Dtrp | L-norvaline | Nva |
| D-tyrosine | Dtyr | α-methyl-aminoisobutyrate | Maib |
| D-valine | Dval | α-methyl-γ-aminobutyrate | Mgabu |
| D-α-methylalanine | Dmala | α-methylcyclohexylalanine | Mchexa |
| D-α-methylarginine | Dmarg | α-methylcyclopentylalanine | Mcpen |
| D-α-methylasparagine | Dmasn | α-methyl-α-napthylalanine | Manap |
| D-α-methylaspartate | Dmasp | α-methylpenicillamine | Mpen |
| D-α-methylcysteine | Dmcys | N-(4-aminobutyl)glycine | Nglu |
| D-α-methylglutamine | Dmgln | N-(2-aminoethyl)glycine | Naeg |
| D-α-methylhistidine | Dmhis | N-(3-aminopropyl)glycine | Norn |
| D-α-methylisoleucine | Dmile | N-amino-α-methylbutyrate | Nmaabu |
| D-α-methylleucine | Dmleu | α-napthylalanine | Anap |
| D-α-methyllysine | Dmlys | N-benzylglycine | Nphe |
| D-α-methylmethionine | Dmmet | N-(2-carbamylethyl)glycine | Ngln |
| D-α-methylornithine | Dmorn | N-(carbamylmethyl)glycine | Nasn |
| D-α-methylphenylalanine | Dmphe | N-(2-carboxyethyl)glycine | Nglu |
| D-α-methylproline | Dmpro | N-(carboxymethyl)glycine | Nasp |
| D-α-methylserine | Dmser | N-cyclobutylglycine | Ncbut |
| D-α-methylthreonine | Dmthr | N-cycloheptylglycine | Nchep |
| D-α-methyltryptophan | Dmtrp | N-cyclohexylglycine | Nchex |
| D-α-methyltyrosine | Dmty | N-cyclodecylglycine | Ncdec |
| D-α-methylvaline | Dmval | N-cyclododeclglycine | Ncdod |
| D-α-methylalnine | Dnmala | N-cyclooctylglycine | Ncoct |
| D-α-methylarginine | Dnmarg | N-cyclopropylglycine | Ncpro |
| D-α-methylasparagine | Dnmasn | N-cycloundecylglycine | Ncund |
| D-α-methylasparatate | Dnmasp | N-(2,2-diphenylethyl)glycine | Nbhm |
| D-α-methylcysteine | Dnmcys | N-(3,3-diphenylpropyl)glycine | Nbhe |
| D-N-methylleucine | Dnmleu | N-(3-indolylyethyl) glycine | Nhtrp |
| D-N-methyllysine | Dnmlys | N-methyl-γ-aminobutyrate | Nmgabu |
| N-methylcyclohexylalanine | Nmchexa | D-N-methylmethionine | Dnmmet |
| D-N-methylornithine | Dnmorn | N-methylcyclopentylalanine | Nmcpen |
| N-methylglycine | Nala | D-N-methylphenylalanine | Dnmphe |
| N-methylaminoisobutyrate | Nmaib | D-N-methylproline | Dnmpro |
| N-(1-methylpropyl)glycine | Nile | D-N-methylserine | Dnmser |
| N-(2-methylpropyl)glycine | Nile | D-N-methylserine | Dnmser |
| N-(2-methylpropyl)glycine | Nleu | D-N-methylthreonine | Dnmthr |
| D-N-methyltryptophan | Dnmtrp | N-(1-methylethyl)glycine | Nva |
| D-N-methyltyrosine | Dnmtyr | N-methyla-napthylalanine | Nmanap |
| D-N-methylvaline | Dnmval | N-methylpenicillamine | Nmpen |
| γ-aminobutyric acid | Gabu | N-(p-hydroxyphenyl)glycine | Nhtyr |
| L-t-butylglycine | Tbug | N-(thiomethyl)glycine | Ncys |
| L-ethylglycine | Etg | penicillamine | Pen |
| L-homophenylalanine | Hphe | L-α-methylalanine | Mala |
| L-α-methylarginine | Marg | L-α-methylasparagine | Masn |
| L-α-methylaspartate | Masp | L-α-methyl-t-butylglycine | Mtbug |
| L-α-methylcysteine | Mcys | L-methylethylglycine | Metg |
| L-α-methylglutamine | Mgln | L-α-methylglutamate | Mglu |
| L-α-methylhistidine | Mhis | L-α-methylhomo phenylalanine | Mhphe |
| L-α-methylisoleucine | Mile | N-(2-methylthioethyl)glycine | Nmet |
| D-N-methylglutamine | Dnmgln | N-(3-guanidinopropyl)glycine | Narg |
| D-N-methylglutamate | Dnmglu | N-(1-hydroxyethyl)glycine | Nthr |
| D-N-methylhistidine | Dnmhis | N-(hydroxyethyl)glycine | Nser |
| D-N-methylisoleucine | Dnmile | N-(imidazolylethyl)glycine | Nhis |
| D-N-methylleucine | Dnmleu | N-(3-indolylyethyl)glycine | Nhtrp |
| D-N-methyllysine | Dnmlys | N-methyl-γ-aminobutyrate | Nmgabu |
| N-methylcyclohexylalanine | Nmchexa | D-N-methylmethionine | Dnmmet |
| D-N-methylornithine | Dnmorn | N-methylcyclopentylalanine | Nmcpen |
| N-methylglycine | Nala | D-N-methylphenylalanine | Dnmphe |
| N-methylaminoisobutyrate | Nmaib | D-N-methylproline | Dnmpro |
| N-(1-methylpropyl)glycine | Nile | D-N-methylserine | Dnmser |
| N-(2-methylpropyl)glycine | Nleu | D-N-methylthreonine | Dnmthr |
| D-N-methyltryptophan | Dnmtrp | N-(1-methylethyl)glycine | Nval |
| D-N-methyltyrosine | Dnmtyr | N-methyla-napthylalanine | Nmanap |
| D-N-methylvaline | Dnmval | N-methylpenicillamine | Nmpen |
| γ-aminobutyric acid | Gabu | N-(p-hydroxyphenyl)glycine | Nhtyr |
| L-t-butylglycine | Tbug | N-(thiomethyl)glycine | Ncys |
| L-ethylglycine | Etg | penicillamine | Pen |
| L-homophenylalanine | Hphe | L-α-methylalanine | Mala |
| L-α-methylarginine | Marg | L-α-methylasparagine | Masn |
| L-α-methylaspartate | Masp | L-α-methyl-t-butylglycine | Mtbug |
| L-α-methylcysteine | Mcys | L-methylethylglycine | Metg |
| L-α-methylglutamine | Mgln | L-α-methylglutamate | Mglu |
| L-α-methylhistidine | Mhis | L-α-methylhomophenylalanine | Mhphe |
| L-α-methylisoleucine | Mile | N-(2-methylthioethyl)glycine | Nmet |
| L-α-methylleucine | Mleu | L-α-methyllysine | Mlys |
| L-α-methylmethionine | Mmet | L-α-methylnorleucine | Mnle |
| L-α-methylnorvaline | Mnva | L-α-methylornithine | Morn |
| L-α-methylphenylalanine | Mphe | L-α-methylproline | Mpro |
| L-α-methylserine | mser | L-α-methylthreonine | Mthr |
| L-α-methylvaline | Mtrp | L-α-methyltyrosine | Mtyr |
| L-α-methylleucine | Mval Nnbhm | L-N-methylhomophenylalanine | Nmhphe |
| N-(N-(2,2-diphenylethyl) | | N-(N-(3,3-diphenylpropyl) | |
| carbamylmethyl-glycine | Nnbhm | carbamylmethyl(1)glycine | Nnbhe |
| 1-carboxy-1-(2,2-diphenyl | Nmbc | | |
| ethylamino)cyclopropane | | | |

Natural aromatic amino acids, Trp, Tyr and Phe, may be substituted for synthetic non-natural acid such as Phenylglycine, TIC, napthylalanine (NaI), phenylisoserine, threoninol, ring-methylated derivatives of Phe, halogenated derivatives of Phe or O-methyl-Tyr and β-amino acids.

The peptides of the present embodiments may include one or more modified amino acids (e.g., biotinylated amino acids) or one or more non-amino acid monomers (e.g. fatty acids, complex carbohydrates etc).

The peptides utilized for forming the nanostructures of the present embodiments can be linear peptides, or cyclic peptides.

In some embodiments of the present invention the peptides composing the peptide nanostructures of the present embodiments comprise one or more aromatic amino acid residue. The advantage of having such peptides is that the aromatic functionalities which are built into the peptide allow the various peptide building blocks to interact through attractive aromatic interactions, to thereby form the nanostructure.

The phrase “aromatic amino acid residue”, as used herein, describes an amino acid residue that has an aromatic moiety, as defined herein, in its side-chain.

Thus, according to some embodiments of the present invention, each of the peptides composing the peptide nanostructures comprises the amino acid sequence X—Y or Y—X, wherein X is an aromatic amino acid residue and Y is any other amino acid residue.

The peptides of the present invention, can be at least 2 amino acid in length.

In some embodiments of the present invention, one or several of the peptides forming the nanostructures is a polyaromatic peptide, which comprises two or more aromatic amino acid residues.

As used herein the phrase “polyaromatic peptides” refers to peptides which include at least 80%, more preferably at least 85%, more preferably at least 90%, more preferably at least 95% or more aromatic amino acid residues. In some embodiments, at least one peptide consists essentially of aromatic amino acid residues. In some embodiments, each peptide consists essentially of aromatic amino acid residues.

Thus for example, the peptides used for forming the nanostructures can include any combination of: dipeptides composed of one or two aromatic amino acid residues; tripeptides including one, two or three aromatic amino acid residues; and tetrapeptides including two, three or four aromatic amino acid residues and so on.

In some embodiments of the present invention, the aromatic amino acid can be any naturally occurring or synthetic aromatic residue including, but not limited to, phenylalanine, tyrosine, tryptophan, phenylglycine, or modificants, precursors or functional aromatic portions thereof.

In some embodiments, one or more peptides in the plurality of peptides used for forming the nanostructures include two amino acid residues, and hence is a dipeptide.

In some embodiments, each of the peptides used for forming the nanostructures comprises two amino acid residues and therefore the nanostructures are formed from a plurality of dipeptides.

Each of these dipeptides can include one or two aromatic amino acid residues. Preferably, but not obligatorily each of these dipeptides includes two aromatic amino acid residues. The aromatic residues composing the dipeptide can be the same, such that the dipeptide is a homodipeptide, or different. Preferably, the nanostructures are formed from homodipeptides.

Hence, in various exemplary embodiments of the invention each peptide in the plurality of peptides used for forming the nanostructures is a homodipeptide composed of two aromatic amino acid residues that are identical with respect to their side-chains residue.

The aromatic amino acid residues used for forming the nanostructures can comprise an aromatic moiety, where the phrase “aromatic moiety” describes a monocyclic or polycyclic moiety having a completely conjugated pi-electron system. The aromatic moiety can be an all-carbon moiety or can include one or more heteroatoms such as, for example, nitrogen, sulfur or oxygen. The aromatic moiety can be substituted or unsubstituted, whereby when substituted, the substituent can be, for example, one or more of alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano and amine.

Exemplary aromatic moieties include, for example, phenyl, biphenyl, naphthalenyl, phenanthrenyl, anthracenyl, [1,10]phenanthrolinyl, indoles, thiophenes, thiazoles and, [2,2′]bipyridinyl, each being optionally substituted. Thus, representative examples of aromatic moieties that can serve as the side chain within the aromatic amino acid residues described herein include, without limitation, substituted or unsubstituted naphthalenyl, substituted or unsubstituted phenanthrenyl, substituted or unsubstituted anthracenyl, substituted or unsubstituted [1,10]phenanthrolinyl, substituted or unsubstituted [2,2′]bipyridinyl, substituted or unsubstituted biphenyl and substituted or unsubstituted phenyl.

The aromatic moiety can alternatively be substituted or unsubstituted heteroaryl such as, for example, indole, thiophene, imidazole, oxazole, thiazole, pyrazole, pyridine, pyrimidine, quinoline, isoquinoline, quinazoline, quinoxaline, and purine. When substituted, the phenyl, naphthalenyl or any other aromatic moiety includes one or more substituents such as, but not limited to, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

As used herein, the term “alkyl” refers to a saturated aliphatic hydrocarbon including straight chain and branched chain groups. Preferably, the alkyl group has 1 to 20 carbon atoms. The alkyl group may be substituted or unsubstituted. When substituted, the substituent group can be, for example, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

A “cycloalkyl” group refers to an all-carbon monocyclic or fused ring (i.e., rings which share an adjacent pair of carbon atoms) group wherein one of more of the rings does not have a completely conjugated pi-electron system. Examples, without limitation, of cycloalkyl groups are cyclopropane, cyclobutane, cyclopentane, cyclopentene, cyclohexane, cyclohexadiene, cycloheptane, cycloheptatriene, and adamantane. A cycloalkyl group may be substituted or unsubstituted. When substituted, the substituent group can be, for example, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

An “alkenyl” group refers to an alkyl group which consists of at least two carbon atoms and at least one carbon-carbon double bond.

An “alkynyl” group refers to an alkyl group which consists of at least two carbon atoms and at least one carbon-carbon triple bond.

An “aryl” group refers to an all-carbon monocyclic or fused-ring polycyclic (i.e., rings which share adjacent pairs of carbon atoms) groups having a completely conjugated pi-electron system. Examples, without limitation, of aryl groups are phenyl, naphthalenyl and anthracenyl. The aryl group may be substituted or unsubstituted. When substituted, the substituent group can be, for example, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

A “heteroaryl” group refers to a monocyclic or fused ring (i.e., rings which share an adjacent pair of atoms) group having in the ring(s) one or more atoms, such as, for example, nitrogen, oxygen and sulfur and, in addition, having a completely conjugated pi-electron system. Examples, without limitation, of heteroaryl groups include pyrrole, furane, thiophene, imidazole, oxazole, thiazole, pyrazole, pyridine, pyrimidine, quinoline, isoquinoline and purine. The heteroaryl group may be substituted or unsubstituted. When substituted, the substituent group can be, for example, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

A “heteroalicyclic” group refers to a monocyclic or fused ring group having in the ring(s) one or more atoms such as nitrogen, oxygen and sulfur. The rings may also have one or more double bonds. However, the rings do not have a completely conjugated pi-electron system. The heteroalicyclic may be substituted or unsubstituted. When substituted, the substituted group can be, for example, lone pair electrons, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine. Representative examples are piperidine, piperazine, tetrahydro furane, tetrahydropyrane, morpholino and the like.

A “hydroxy” group refers to an —OH group.

A “thio”, “thiol” or “thiohydroxy” group refers to and —SH group.

An “azide” group refers to a —N═N≡N group.

An “alkoxy” group refers to both an —O-alkyl and an -O-cycloalkyl group, as defined herein.

An “aryloxy” group refers to both an —O-aryl and an —O-heteroaryl group, as defined herein.

A “thiohydroxy” group refers to and —SH group.

A “thioalkoxy” group refers to both an —S-alkyl group, and an —S-cycloalkyl group, as defined herein.

A “thioaryloxy” group refers to both an —S-aryl and an —S-heteroaryl group, as defined herein.

A “halo” or “halide” group refers to fluorine, chlorine, bromine or iodine.

A “trihaloalkyl” group refers to an alkyl substituted by three halo groups, as defined herein. A representative example is trihalomethyl.

An “amino” group refers to an —NR′R″ group where R′ and R″ are hydrogen, alkyl, cycloalkyl or aryl.

A “nitro” group refers to an —NO₂ group.

A “cyano” group refers to a group.

Representative examples of homodipeptides that can be used to form the nanostructures of the present embodiments include, without limitation, a naphthylalanine-naphthylalanine dipeptide, phenanthrenylalanine-phenanthrenylalanine dipeptide, anthracenylalanine-anthracenylalanine dipeptide, [1,10]phenanthrolinylalanine-[1,10]phenanthrolinylalanine dipeptide, [2,2′]bipyridinylalanine-[2,2′]bipyridinylalanine dipeptide, (pentahalo-phenylalanine)-(pentahalo-phenylalanine) dipeptide, phenylalanine-phenylalanine dipeptide, (amino-phenylalanine)-(amino-phenylalanine) dipeptide, (dialkylamino-phenylalanine)-(dialkylamino-phenylalanine) dipeptide, (halophenylalanine)-(halophenylalanine) dipeptide, (alkoxy-phenylalanine)-(alkoxy-phenylalanine) dipeptide, (trihalomethyl-phenylalanine)-(trihalomethyl-phenylalanine) dipeptide, (4-phenyl-phenylalanine)-(4-phenyl-phenylalanine) dipeptide and (nitro-phenylalanine)-(nitro-phenylalanine) dipeptide.

According to various exemplary embodiments of the present invention the peptide nanostructures are composed from a plurality of diphenylalanine (Phe-Phe) homodipeptides.

In some embodiments of the present invention one or more peptides in the plurality of peptides used to form the nanostructures is an end-capping modified peptide.

The phrase “end-capping modified peptide”, as used herein, refers to a peptide which has been modified at the N-(amine)terminus and/or at the C-(carboxyl)terminus thereof. The end-capping modification refers to the attachment of a chemical moiety to the terminus, so as to form a cap. Such a chemical moiety is referred to herein as an end-capping moiety and is typically also referred to herein and in the art, interchangeably, as a peptide protecting moiety or group.

The phrase “end-capping moiety”, as used herein, refers to a moiety that when attached to the terminus of the peptide, modifies the end-capping. The end-capping modification typically results in masking the charge of the peptide terminus, and/or altering chemical features thereof, such as, hydrophobicity, hydrophilicity, reactivity, solubility and the like. Examples of moieties suitable for peptide end-capping modification can be found, for example, in Green et al., “Protective Groups in Organic Chemistry”, (Wiley, second ed. 1991) and Harrison et al., “Compendium of Synthetic Organic Methods”, Vols. 1-8 (John Wiley and Sons, 1971-1996).

The use of end-capping modification, allows controling the chemical properties and charge of the nanostructures, hence also the way the peptide nanostructures of the present embodiments are assembled and/or aligned.

Changing the charge of one or both termini of one or more of the peptides may result in altering the morphology of the resulting nanostructure and/or the way the resulting nanostructure responds to, for example, an electric and/or magnetic fields.

End-capping of a peptide can be used to modify its hydrophobic/hydrophilic nature. Altering the hydrophobic/hydrophilic property of a peptide may result, for example, in altering the morphology of the resulting nanostructure and/or the aqueous solubility thereof. By selecting the percentage of the end-capping modified peptides and the nature of the end capping modification, the hydrophobicity/hydrophilicity, as well as the solubility of the nanostructure can be finely controlled. For example, the end capping modification can be selected to control adherence of nanoparticles to the wall of the nanostructures.

While reducing the present invention to practice, the present inventors have uncovered that modifying the end-capping of a peptide does not abolish its capacity to self-assemble into nanostructures, similar to the nanostructures formed by unmodified peptides. The persistence of the end-capping modified peptides to form nanostructures supports the hypothesis of the present inventors according to which the dominating characteristic required to form peptides nanostructures is the aromaticity of its side-chains, and the π-stacking interactions induced thereby, as previously described in, for example WO 2004/052773 and WO 2004/060791, the contents of which are hereby incorporated by reference.

It was further found by the present inventors that the aromatic nature of at least one of the end-capping of the peptide affects the morphology of the resulting nanostructure. For example, it was found that an unmodified peptide or a peptide modified with a non-aromatic end-capping moiety can self-assemble to a tubular nanostructure.

Representative examples of N-terminus end-capping moieties suitable for the present embodiments include, but are not limited to, formyl, acetyl (also denoted herein as “Ac”), trifluoroacetyl, benzyl, benzyloxycarbonyl (also denoted herein as “Cbz”), tert-butoxycarbonyl (also denoted herein as “Boc”), trimethylsilyl (also denoted “TMS”), 2-trimethylsilyl-ethanesulfonyl (also denoted “SES”), trityl and substituted trityl groups, allyloxycarbonyl, 9-fluorenylmethyloxycarbonyl (also denoted herein as “Fmoc”), and nitro-veratryloxycarbonyl (“NVOC”).

Representative examples of C-terminus end-capping moieties suitable for the present embodiments are typically moieties that lead to acylation of the carboxy group at the C-terminus and include, but are not limited to, benzyl and trityl ethers as well as alkyl ethers, tetrahydropyranyl ethers, trialkylsilyl ethers, allyl ethers, monomethoxytrityl and dimethoxytrityl. Alternatively the —COOH group of the C-terminus end-capping may be modified to an amide group.

Other combination of N-terminus end capping and C-terminus end capping of the various peptides composing the nanostructure are also included in the scope of the present invention. These include, for example, the presence of certain percents of end-capping modified peptides, whereby the peptides are modified at the N-termini and/or the C-termini.

End-capping modifications of peptides may include replacement of the amine and/or carboxyl with a different moiety, such as hydroxyl, thiol, halide, alkyl, aryl, alkoxy, aryloxy and the like, as these terms are defined hereinbelow.

In some embodiments of the present invention, all of the peptides that form the nanostructures are end-capping modified. In one embodiment, the peptides are modified only at the N-termini or the C-termini thereof, resulting in a nanostructure that has a negative net charge or a positive net charge, respectively. In another embodiment, the peptides are modified at both the N-termini and the C-termini, resulting in an uncharged nanostructure.

End-capping moieties can be further classified by their aromaticity. Thus, end-capping moieties can be aromatic or non-aromatic.

Representative examples of non-aromatic end capping moieties suitable for N-terminus modification include, without limitation, formyl, acetyl trifluoroacetyl, tert-butoxycarbonyl, trimethylsilyl, and 2-trimethylsilyl-ethanesulfonyl. Representative examples of non-aromatic end capping moieties suitable for C-terminus modification include, without limitation, amides, allyloxycarbonyl, trialkylsilyl ethers and allyl ethers.

Representative examples of aromatic end capping moieties suitable for N-terminus modification include, without limitation, fluorenylmethyloxycarbonyl (Fmoc). Representative examples of aromatic end capping moieties suitable for C-terminus modification include, without limitation, benzyl, benzyloxycarbonyl (Cbz), trityl and substituted trityl groups.

When the nanostructures of the present embodiments comprise one or more dipeptides, the dipeptides can be collectively represented by the following general Formula I:

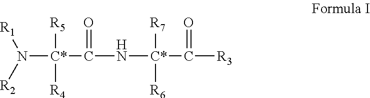

where:

C* is a chiral or non-chiral carbon; R₁ and R₂ are each independently selected from the group consisting of hydrogen, alkyl, cycloalkyl, aryl, carboxy, thiocarboxy, C-carboxylate and C-thiocarboxylate; R₃ is selected from the group consisting of hydroxy, alkoxy, aryloxy, thiohydroxy, thioalkoxy, thioaryloxy, halo and amine; and each of R₄-R₇ is independently selected from the group consisting of hydrogen, alkyl, cycloalkyl, aryl, heteroaryl, heteroalicyclic, hydroxy, thiohydroxy (thiol), alkoxy, aryloxy, thioalkoxy, thioaryloxy, C-carboxylate, C-thiocarboxylate, N-carbamate, N-thiocarbamate, hydrazine, guanyl, and guanidine, as these terms are defined herein, provided that at least one of R₄-R₇ comprises an aromatic moiety, as defined hereinabove.

Also contemplated are embodiments in which one or more of R₄-R₇ is other substituent, provided that at least one comprises an aromatic moiety.

Also contemplated are embodiments in which one or more of R₁-R₃ is the end-capping moieties described hereinabove.

Depending on the substituents, each of the C* carbon atoms in each of the compounds described above, can be chiral or non-chiral. Any chiral carbon atom that is present in the peptides of the present embodiments can be in D-configuration, L-configuration or racemic. Thus, the present embodiments encompass any combination of chiral and racemic carbon atoms, including all the possible stereoisomers, optical isomers, enantiomers, and anomers. The peptides of the present embodiments can be synthesized while retaining a configuration of the reactants (e.g., the amino acids). Hence, by selecting the configuration of the reactants (e.g., amino acids) and the appropriate syntheses conditions, the optical purity (e.g., the inclusion of chiral and/or racemic carbons) and the obtained stereoisomers of the resulting peptides can be determined. In cases where racemic mixtures are obtained, known techniques can be used to separate the optical or stereo-isomers. Such techniques are described, for example, in “Organic chemistry, fourth Edition by Paula Yurkanis Bruice, page 180-185 and page 214, Prentice Hall, Upper Sadde River, N.J. 07458.”

As stated, the nanostructures of the present embodiments can be generated from linear or cyclic peptides.

Cyclic peptides constitute a unique end-capping modified peptide as the modification may be the cyclizing bond (between the amine of the N-terminus and the carboxyl of the C-terminus), and can either be synthesized in a cyclic form or configured so as to assume a cyclic form under desired conditions (e.g., physiological conditions).

For example, a peptide according to the teachings of the present invention can include at least two cysteine residues flanking the core peptide sequence. In this case, cyclization can be generated via formation of S—S bonds between the two Cys residues. Side-chain to side chain cyclization can also be generated via formation of an interaction bond of the formula —(—CH₂-)n-S—CH₂—C—, wherein n=1 or 2, which is possible, for example, through incorporation of Cys or homoCys and reaction of its free SH group with, e.g., bromoacetylated Lys, Orn, Dab or Dap. Furthermore, cyclization can be obtained, for example, through amide bond formation, e.g., by incorporating Glu, Asp, Lys, Orn, di-amino butyric (Dab) acid, di-aminopropionic (Dap) acid at various positions in the chain (—CO—NH or —NH—CO bonds). Backbone to backbone cyclization can also be obtained through incorporation of modified amino acids of the formulas H—N((CH₂)n-COOH)—C(R)H—COOH or H—N((CH₂)n-COOH)—C(R)H—NH₂, wherein n=1-4, and further wherein R is any natural or unnatural side chain of an amino acid.

The end-capping modification of the peptides forming the nanostructures described herein can be further utilized for incorporating into the nanostructure a labeling moiety. Nanostructures composed of such labeled peptides can be utilized in a variety of applications, including, for example, tracing and tracking location of nanoelements composed of the nanostructures of the present invention in mechanical devices and electronic circuitry; and tracing, tracking and diagnosing concentrations of the nanostructures of the present invention in a living tissue, cell or host.

Thus, according to an embodiment of the present invention, the one or more end-capping modified peptide comprises a labeling moiety. The labeling moiety can form a part of the end-capping moiety or can be the end-capping moiety itself.

As used herein, the phrase “labeling moiety” describes a detectable moiety or a probe which can be identified and traced by a detector using known techniques such as IR, NMR, X-ray diffraction and imaging, HPLC, PET, SPECT, MRI, CT and the like.

Representative examples of labeling moieties include, without limitation, fluorescent moieties, chromophores, phosphorescent moieties, radioactive labeling moieties, heavy metal clusters, as well as any other known detectable moieties.

As used herein, the term “chromophore” refers to a chemical moiety that, when attached to an end-capping moiety or is an end-capping moiety, renders the latter colored and thus visible when various spectrophotometric measurements are applied.

The phrase “fluorescent moiety” refers to a chemical moiety that emits light at a specific wavelength during exposure to radiation from an external source.

The phrase “phosphorescent moiety” refers to a chemical moiety emitting light without appreciable heat or external excitation as by slow oxidation of phosphorous.

A heavy metal cluster can be for example a cluster of gold atoms used, for example, for labeling in electron microscopy or X-ray imaging techniques.

Radiolabeled compounds can be almost any chemical moiety into which a radioactive isotope is incorporated. A radioactive isotope is an element which emits radiation and includes, for example, an α-radiation emitters, a β-radiation emitters or a γ-radiation emitters.

In one example, wherein the Fmoc described hereinabove is used as the end-capping moiety, the end-capping moiety itself is a fluorescent labeling moiety.

In another example, wherein the Fmoc described hereinabove further includes a radioactive fluoro atom (¹⁸F) is used as the end-capping moiety, the end-capping moiety itself is a radioactive labeling moiety.

The peptide nanostructures of the present embodiments can further comprise a functional group, preferably a plurality of functional groups.

The functional group can be, for example, a group such as, but not limited to, thiol, hydroxy, halo, carboxylate, amine, amide, nitro, cyano, hydrazine, and the like, a hydrophobic moiety, such as, but not limited to, medium to high alkyls, cycloalkyls and aryls, and/or a metal ligand.

When the nanostructures of the present embodiments have a tubular structure, it can be filled with a filler material.

For example, the nanostructures may enclose conductor or semiconductor materials, including, without limitation, inorganic structures such as Group IV, Group III/Group V, Group II/Group VI elements, transition group elements, or the like.

As used herein, the term “Group” is given its usual definition as understood by one of ordinary skill in the art. For instance, Group II elements include Zn, Cd and Hg; Group III elements include B, Al, Ga, In and Tl; Group IV elements include C, Si, Ge, Sn and Pb; Group V elements include N, P, As, Sb and Bi; and Group VI elements include O, S, Se, Te and Po.

Thus, for conducting materials, the nanostructures may enclose, for example, silver, gold, copper, platinum, nickel, or palladium. For semiconductor materials the nanostructures may enclose, for example, silicon, indium phosphide, gallium nitride and others.

The nanostructures may also encapsulate, for example, any organic or inorganic molecules that are polarizable or have multiple charge states. For example, the nanostructures may include main group and metal atom-based wire-like silicon, transition metal-containing wires, gallium arsenide, gallium nitride, indium phosphide, germanium, or cadmium selenide structures.

Additionally, the nanostructure of the present invention may enclose various combinations of materials, including semiconductors and dopants. Representative examples include, without limitations, silicon, germanium, tin, selenium, tellurium, boron, diamond, or phosphorous. The dopant may also be a solid solution of various elemental semiconductors, for example, a mixture of boron and carbon, a mixture of boron and P, a mixture of boron and silicon, a mixture of silicon and carbon, a mixture of silicon and germanium, a mixture of silicon and tin, or a mixture of germanium and tin. In some embodiments, the dopant or the semiconductor may include mixtures of different groups, such as, but not limited to, a mixture of a Group III and a Group V element, a mixture of Group III and Group V elements, a mixture of Group II and Group VI semiconductors. Additionally, alloys of different groups of semiconductors may also be possible, for example, a combination of a Group II-Group VI and a Group III-Group V semiconductor and a Group I and a Group VII semiconductor.

Specific and representative examples of semiconductor materials which can be encapsulated by the nanostructure of the present invention include, without limitation, CdS, CdSe, ZnS and SiO₂.

The nanostructure of the present invention may also enclose a thermoelectric material that exhibits a predetermined thermoelectric power. Preferably, such a material is selected so that the resulting nanostructure composition is characterized by a sufficient figure of merit. Such composition, as further detailed hereinunder, may be used in thermoelectric systems and devices as heat transfer media or thermoelectric power sources. According to a preferred embodiment of the present invention the thermoelectric material which can be encapsulated in the nanostructure of the present invention may be a bismuth-based material, such as, but not limited to, elemental bismuth, a bismuth alloy or a bismuth intermetallic compound. The thermoelectric material may also be a mixture of any of the above materials or other materials known to have thermoelectric properties. In addition the thermoelectric material may also include a dopant. Representative examples include, without limitation, bismuth telluride, bismuth selenide, bismuth antimony telluride, bismuth selenium telluride and the like. Other materials are disclosed, for example, in U.S. Patent Application No. 20020170590.

The nanostructure of the present invention may also enclose magnetic materials. Generally, all materials in nature posses some kind of magnetic properties which are manifested by a force acting on a specific material when present in a magnetic field. These magnetic properties, which originate from the sub-atomic structure of the material, are different from one substrate to another. The direction as well as the magnitude of the magnetic force is different for different materials.

Whereas the direction of the force depends only on the internal structure of the material, the magnitude depends both on the internal structure as well as on the size (mass) of the material. The internal structure of the materials in nature, to which the magnetic characteristics of matter are related, is classified according to one of three major groups: diamagnetic, paramagnetic and ferromagnetic materials, where the strongest magnetic force acts on ferromagnetic materials.

In terms of direction, the magnetic force acting on a diamagnetic material is in opposite direction than that of the magnetic force acting on a paramagnetic or a ferromagnetic material. When placed in external magnetic field, a specific material acquires a non-zero magnetic moment per unit volume, also known as a magnetization, which is proportional to the magnetic field vector. For a sufficiently strong external magnetic field, a ferromagnetic material, due to intrinsic non-local ordering of the spins in the material, may retain its magnetization, hence to become a permanent magnet. As opposed to ferromagnetic materials, both diamagnetic and paramagnetic materials loose the magnetization once the external magnetic field is switched off.

Representative examples of paramagnetic materials which can be enclosed by the nanostructure of the present invention include, without limitation, cobalt, copper, nickel, and platinum. Representative examples of ferromagnetic materials include, without limitation, magnetite and NdFeB.

Other materials which may be encapsulated by the nanostructure of the present invention include, without limitation, light-emitting materials (e.g., dysprosium, europium, terbium, ruthenium, thulium, neodymium, erbium, ytterbium or any organic complex thereof), biominerals (e.g., calcium carbonate) and polymers (e.g., polyethylene, polystyrene, polyvinyl chloride, polynucleotides and polypeptides).

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, an and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

This Example describes experiments in which peptide nanotubes were immobilized onto electrode structures by dielectrophoresis (DEP), according to some embodiments of the present invention.

### Materials and Methods

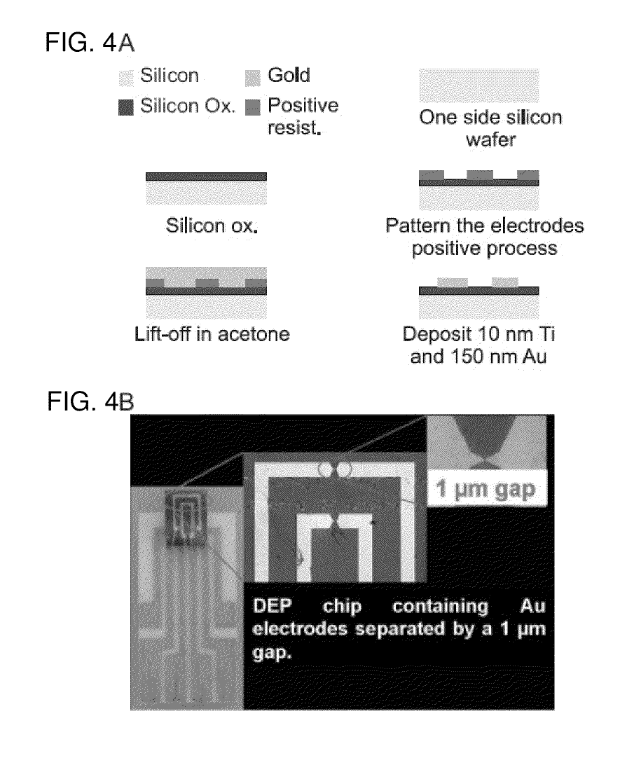

A DEP microchip was fabricated according to some embodiments of the present invention by optical lithography on a silicon wafer following a protocol previously described in Dimaki, M. and Boggild, P., Nanotechnology 2005, 16, 759-763. Briefly, SiO₂ was grown on top of a silicon wafer as an insulating layer. A 1.5 m resist layer was spun on top of the oxide and a positive photolithography process was used in order to pattern the electrodes on the oxide. After development of the resistance 10 nm of titanium and 150 nm of gold were deposited on the wafer and a lift-off process using acetone was carried out to define the electrodes. The titanium layer enhanced the adhesion between the gold and the silicon oxide layer. FIG. 4A illustrates the fabrication steps. The final DEP microchip including the separation gap between the gold microelectrodes is shown in FIG. 4B.

Diphenylalanine peptide was purchased from Bachem (Cat. No. G-2925, Germany). Fresh stock solutions were prepared by dissolving the lyophilized form of the peptide in 1,1,1,3,3,3-hexafluoro-2-propanol (Sigma Aldrich) at a final concentration of 100 mg/mL. Fresh solutions were prepared before each experiment.

Peptide stock solution was diluted in distilled water to a final concentration of 2 mg/mL. An aliquot of 2 mg/mL peptide solution was placed on top of the microelectrodes. The alternating current voltage was then turned on and the different parameters were applied: frequency, potential magnitude, and time. Voltage amplitudes from 1 to 10 V peak-peak, frequencies from 0.1 to 10 MHz, and times ranging from 30 s to 5 min were applied on the electrodes for the DEP experiment. After the chosen time was finished the voltage was turned off and the excess of solvent was removed from the chip by using a stream of nitrogen.

SEM images were carried out with a LEO 1550 Scanning Electron Microscope with EDX. Previous to the SEM imaging the amyloid peptide nanotubes were covered with a gold layer using a Hummer gold sputtering system.

Atomic force microscopy (AFM) images were carried out with a Veeco CP-II Scanning Probe Microscope (Veeco Systems). Images of peptide nanotubes were obtained in AFM taping mode in air using an ElectriTap 300 probe (Budget Sensors).

I-V data were acquired using a low-noise current pre-amplifier Model SR570 (Stanford Research Systems) and a BNC-211 adapter (National Instruments). The I-V data were used for constructing I-V curves.

### Results

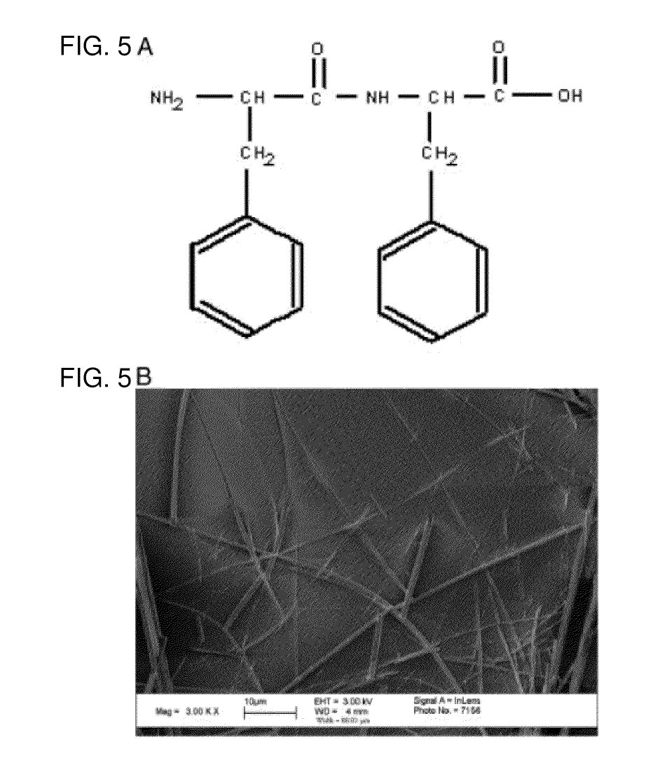

Amyloid peptide nanotubes were obtained by dissolving aliquots of a concentrated diphenylalanine peptide stock solution in water. The chemical structure of the peptide used in this example is shown in FIG. 5A. The fabricated peptide nanotubes were imaged using SEM. Initial analysis showed the formation of long and thick peptide nanotube bundles (FIG. 5B). In order to obtain more separate nanotube bundles and even individual nanotubes a lesser concentrated solution, 0.5 mg/mL, was prepared.

In the present example, peptide nanotubes were manipulated by DEP. Prior to the DEP experiments, a two-dimensional simulation by Comsol Multiphysics® software was used to simulate the electrical field on the fabricated microelectrodes with a 1 m gap. For the simulation, the permittivity of water was m=80, and the applied potential was 10 V peak-peak.

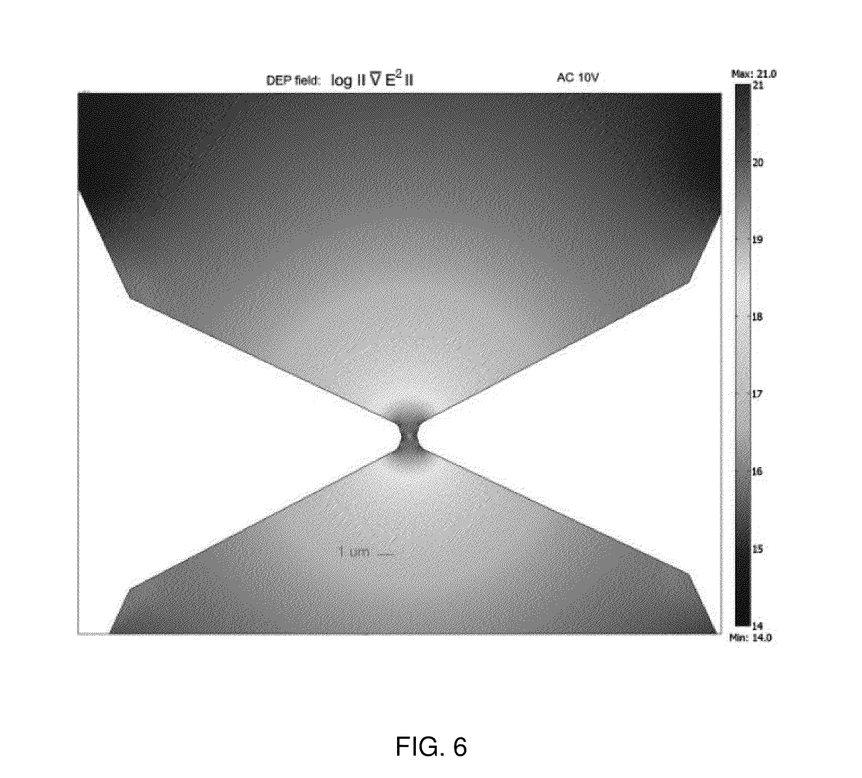

The result of the simulation is shown in FIG. 6. The maximum of the DEP field, indicated by the red color is situated at the tip of the gold microelectrodes. In this way the amyloid peptide nanotubes were expected to be trapped between the two tips of the gold microelectrodes. The nanotubes were not included in the simulation since their dielectric constant was unknown.

For the DEP experiments a drop of the peptide nanotube suspension (5 L) with a concentration of 2 mg/mL was applied on top of the chip with a micropipette. The DEP microchip was connected to the function generator through a custom-made holder. The frequency generator was thereafter switched on for a period of 5 min. The generator was then turned off and the drop was blown off the surface with a nitrogen stream. For the DEP experiments alternating current voltage with frequency values from 0.1 to 10 MHz, amplitude from 1 to 10 V for times ranging between 30 s and 5 min were evaluated. Different parameter combinations were tested. Normally, the positive DEP response for particles shows a broad maximum as a function of frequency rather than a sharp maximum. Amyloid peptide bundles were successfully deposited on top of the microelectrodes for an alternating current voltage of 10 V with a frequency of 1 MHz was applied for a period of 5 minutes.

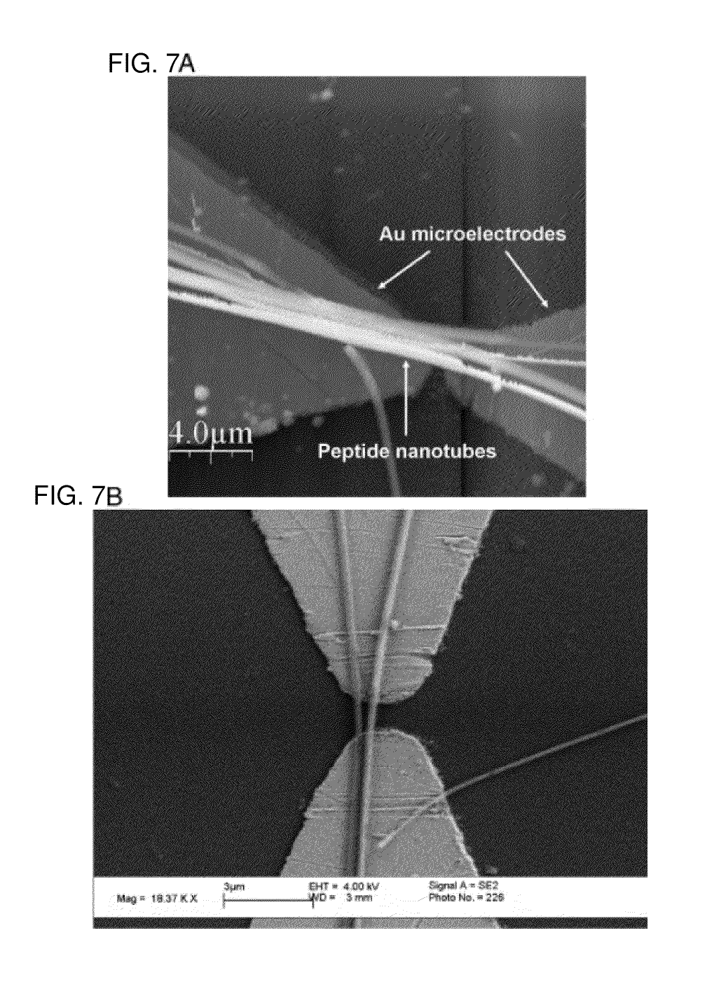

A typical result of the immobilization of amyloid peptide nanotubes bundles onto a gold microelectrode is shown in FIGS. 7A and 7B. These show an AFM and an SEM image of amyloid peptide nanotubes respectively, connecting two gold microelectrodes. The nanotubes are aligned along the two-microelectrode tips after the DEP experiment.

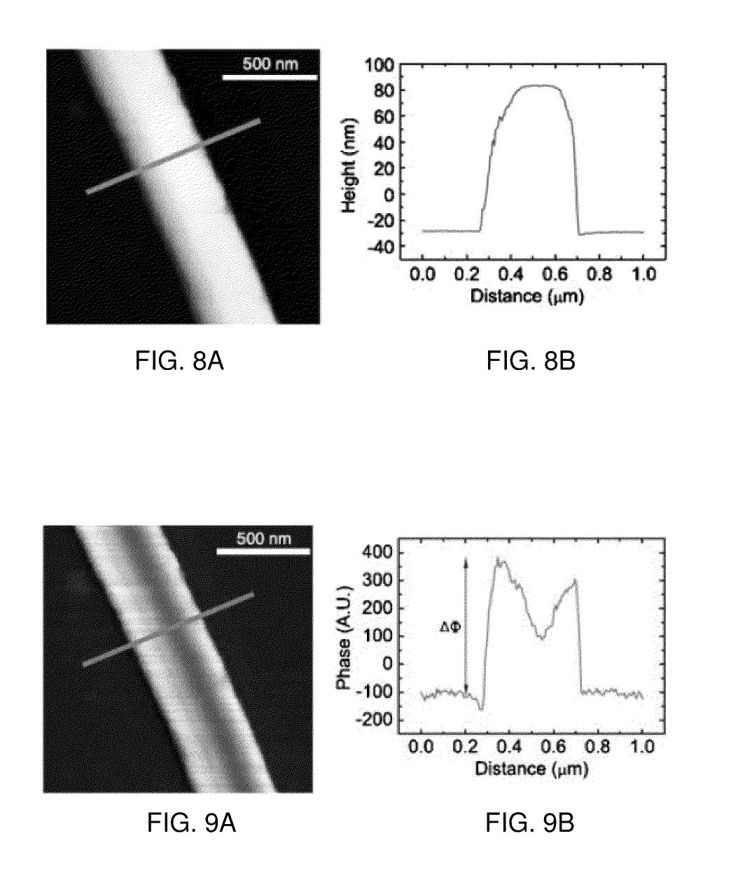

For the immobilization of a single amyloid peptide nanotube, a more dilute, 0.5 mg/mL, peptide solution was prepared. In this way more separate peptide nanotubes were obtained. Single amyloid peptide nanotubes were previously imaged using AFM (FIGS. 8A and 8B). The topography line scan in FIG. 8A shows a smooth peptide nanotube surface without any large features. The height of this peptide nanotube above the surface was 83±5 nm, as measured from the topography line scan shown in FIG. 8B. A phase image and a phase scan of the same peptide nanotube are shown in FIGS. 9A and 9B, respectively. The phase scan contains a dip in the centre, indicating hollow nature of the peptide nanotubes. The dip was characteristic of all phase scans.

More details regarding the qualitative mapping of the nanotubes are provided in Example 2, below.

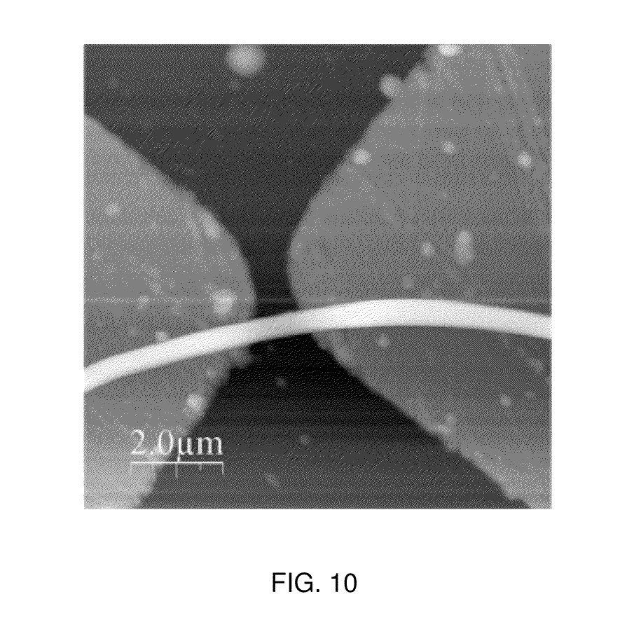

FIG. 10 is an AFM image of a single amyloid peptide nanotube immobilized on top of gold microelectrodes using DEP.

The electrical behavior of the immobilized amyloid peptide nanotubes was evaluated by constructing an I-V curve. Previously, binding of the nanotubes to the microelectrodes and bridging of the gap between the gold microelectrodes was confirmed by AFM. Passing current through this set-up allowed a reading of the current (I) and voltage (V), and the I-V curve for amyloid nanotube bundles was recorded.

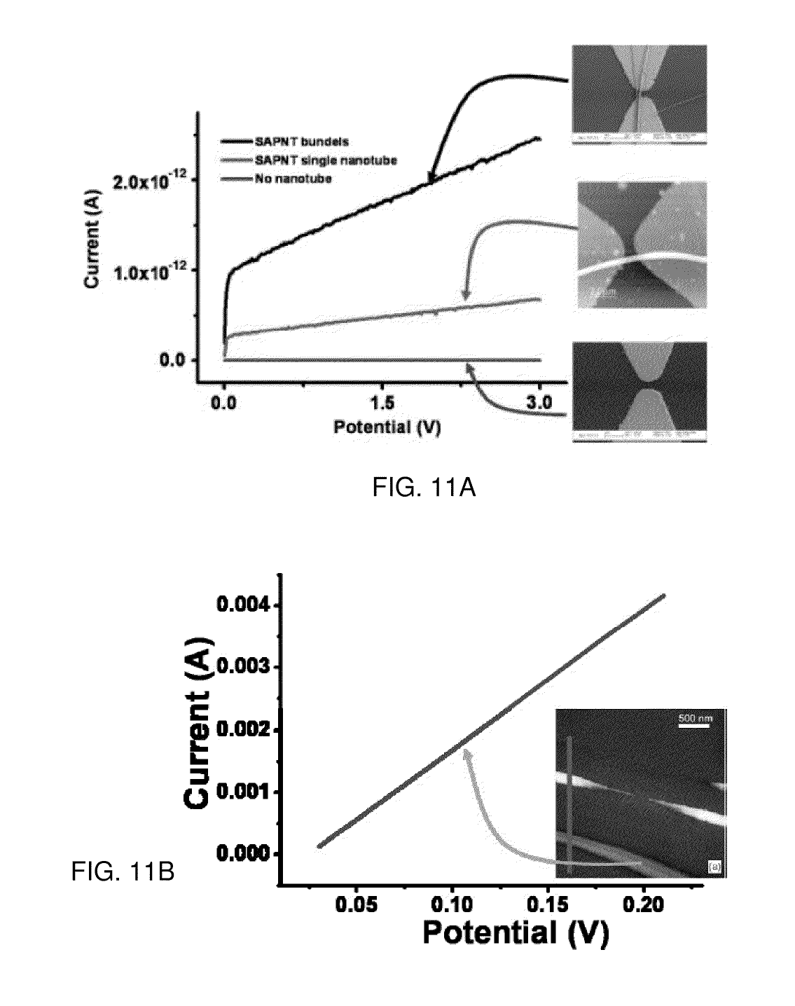

FIG. 11A shows I-V curves of amyloid peptide nanotube bundles (black line) and a single amyloid peptide nanotube (red line) bridging the gap between the two microelectrodes. Also shown (blue line) is an I-V curve of a control experiment for the empty holder. As shown the I-V curves of the single nanotube and bundle of nanotubes are linear, demonstrate ohmic conductivity with high resistance. This behaviour confirms the insulator properties of this kind of biological nanotubes. The current transmitted through the immobilized nanotubes after an applied potential of 0-3 V was in the pA range, (black line). The jump from about 0 A to about 10⁻¹² A is due to the offset voltage when potential is applied at the beginning of the experiment. The low conductivity of the self-assembled amyloid peptide nanotubes (SAPNT) was confirmed when the I-V curve was plotted for a single SAPNT bridging the gap between the two gold microelectrodes (red line). In this case the conductivity was even lower than that for the immobilized SAPNT bundles. As a control experiment an I-V curve using the same type of DEP chip but without any nanotube immobilized on top was done. In this case a flat line showing zero conductivity was obtained (blue line). Surprisingly, the nanotubes were still present on the microelectrodes after several potential cycles from 0 to 3 V were applied. This is an indication of the resistance of the nanotubes to high voltages.

FIG. 11B shows an I-V curve for a silver filled peptide nanotube. As shown, there is a substantial increase in the current due to the presence of silver inside the peptide nanotube. About 10⁹ times increment was observed, compared with the current obtained when an empty peptide nanotube bridging the gold microelectrodes (FIG. 11A).

### Example 2

This Example describes experiments performed according to some embodiments of the present invention for qualitative mapping of structurally different polypeptide nanotubes.

Electrostatic force microscopy (SPM) was used to distinguish between diphenylalanine nanotubes, silver filled nanotubes and silver wires placed on pre-fabricated SiO₂ surfaces with a backgate. Substrates for the experiments were fabricated by the use of four inch 350 μm thick heavily p-doped silicon wafers. A 100 nm thick silicon oxide layer was grown on the substrates, the oxide on the back was removed by HF and a 20 nm layer was evaporated on the backside followed by a 500 nm layer of gold. For the casting of silver nanowires inside the peptide nanotubes an aliquot of 10 μL, of a boiling solution of AgNO₃ was added to 90 μL, of a peptide nanotubes solution (aged for 1 night). After this 6 μL, of a solution of 1% citric acid was added until a final concentration of 0.038% citric acid was reached to serve as a reducing agent [Tjernberg et al., 1996]. For the enzymatic degradation of the peptide nanotubes the silver peptide nanotubes were incubated with Proteinase K at a final concentration of 100 μg/mL for 1 hour at 37° C. The solutions with the peptide and silver wires were then added onto the fabricated substrates.

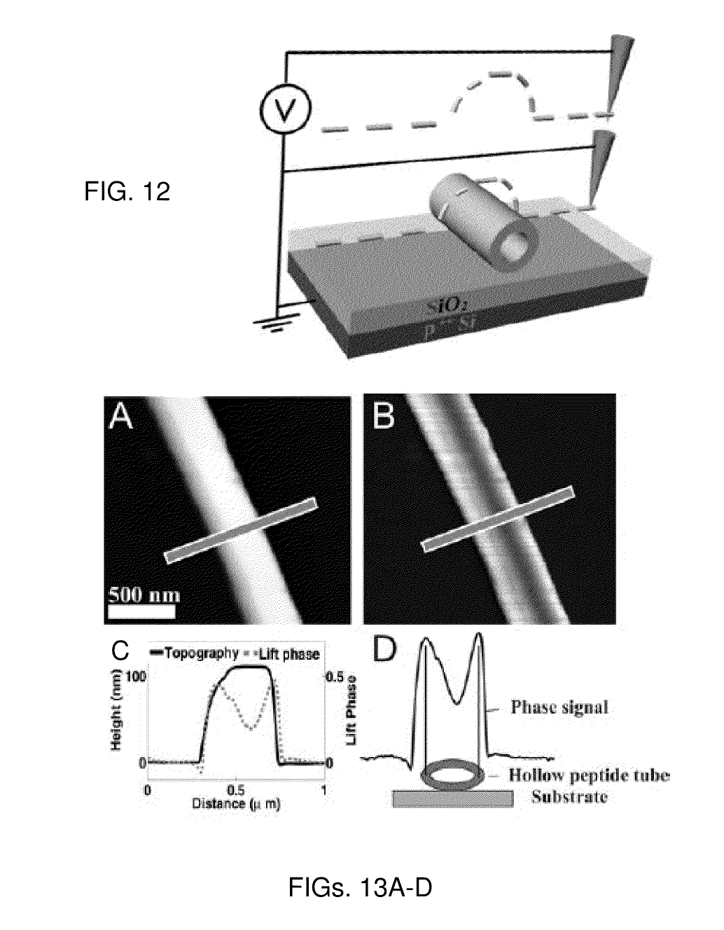

The EFM phase mode method is known in the art and found, for example, in previous Borkrath, M. et al., 2002 and Zhou, Y. et al., 2003. The working principle of EFM is illustrated in FIG. 12 and can be outlined as follows. First a line scan acquires the topography in tapping mode, with no bias applied between the tip and the doped substrate. Then, the tip is raised a few tens of nanometers above the sample, a potential is applied, and the tip retraces the topography of the previous scan at a constant height over the sample.

During the second scan the phase of the oscillation, φ, of the cantilever is recorded. Since the tip is raised some tens of nanometer and due to the potential difference between the tip and the substrate it can be assumed that the only force acting on the cantilever is an electrostatic force, F, caused by the applied potential. According to Staii et. al. and Jepersen et. al., the phase is proportional to the derivative of force acting on the cantilever or

$$φ \approx - \frac{Q}{k} \frac{\partial F}{\partial z} \qquad ( EQ . 1 )$$

where Q is the quality factor, k the spring constant of the cantilever, and z is the distance between the tip and the doped substrate. The derivative of the force can be written as

$$\frac{\partial F}{\partial z} \approx \frac{1}{2} \frac{{\partial }^{2} C}{\partial {z}^{2}} {V}^{2} \qquad ( EQ . 2 )$$

where C is the capacitance between the tip and the substrate and V is the potential difference between the tip and the substrate. From Equation 2 it can be seen that changes in the phase can only be caused by changes in the capacitance, so in this case by changes in the material between the tip and the cantilever. Therefore, changes in the phase can be written as

$$Δφ \approx \frac{Q}{2 k} ( \frac{{\partial }^{2} {C}_{1}}{\partial {z}^{2}} - \frac{{\partial }^{2} {C}_{2}}{\partial {z}^{2}} ) {V}^{2} \qquad ( EQ . 3 )$$

where C1 is the capacitance between the tip and the substrate without a sample inserted and C2 is the capacitance between tip and substrate with the sample introduced.

The interaction of the substrate with the cone of the tip and the cantilever beam can be neglected as the interaction is mostly constant. Further, calculations indicate that for optimal readout, changes in height is in the range of 10 to 50 nm Taking this into account and modeling the tip substrate interaction as a plate capacitor, where the shape of the cantilever tip is assumed to be a flat disk with radius rₜᵢₚ, the change in the lift phase can be expressed by [Jepersen et al.; Caisii et al.]

$$Δφ \approx \frac{Q π {r}_{tip}^{2} {ɛ}_{0}}{k} ( \frac{1}{{( x + t / {ɛ}_{SiO 2} )}^{3}} - \frac{1}{{( x + t / {ɛ}_{SiO 2} + h / {ɛ}_{P} )}^{3}} ) {V}^{2} \qquad ( EQ . 3 )$$

where ε₀ is the vacuum permittivity, x is the lift height, t the height of the oxide layer ε_{SiO2} is the permittivity of the oxide, h the height of the sample, and ε_{P} is the permittivity of the sample.

A total of 22 polypeptide tubes were scanned and their topography height was in the range of 50 to 190 nm. A topography scan and a lift phase scan of a single hollow peptide nanotube are shown in FIGS. 13A and 13B, and line profiles outlined in these scans are plotted in FIG. 13C. A dip in the phase line profile is observed in the centre of the peptide nanotubes. From Equation 2 the dip in the phase can be explained by a change in the capacitance between the tip and substrate, which in turn from Equation 4 indicates a change in the dielectric properties of the tube. Such a change can be the presence of hollow tubes, as shown in FIG. 13D, since in that case the permittivity of the tubes would decrease in the middle, where air is present.

The dip was observable for nanotube topography height down to 60 nm. For nanotubes with a smaller diameter the dip began to be unobservable, most likely due to the dimensions of the AFM tip, as the radius is around 25 nm.

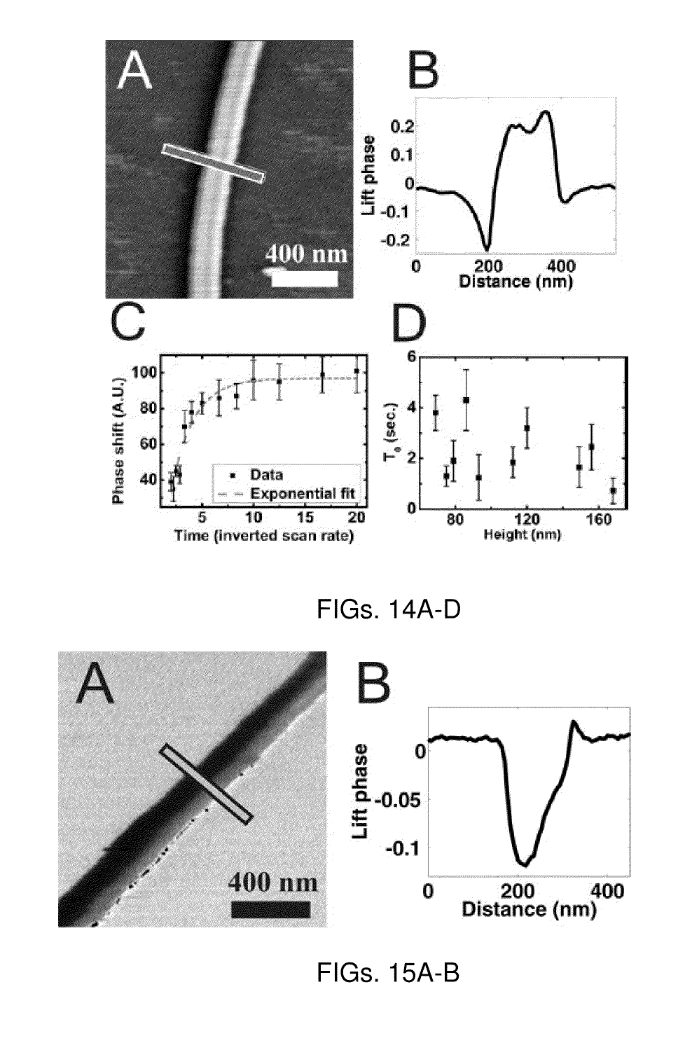

A total of 34 silver filled peptide nanotubes were scanned and their topography height was in the range of 70 to 170 nm. The lift phase for a silver-filled peptide tube is shown in FIG. 14a, while FIG. 14b shows the line profile illustrated by the gray line in FIG. 14a. The phase shift for the silver-filled peptide tube resembles the signal which Staii et. al. measured for conducting Pan.HCSA/PEO nanofibers using the EFM method, indication that the silver-filled peptide nanotubes have similar electrical properties. The signal shows a negative-positive phase shift response. Staii et. al. explanation for this behavior is the existence of an additional attractive force, which interacts between the tip and the silver filled nanotube, as the tip approaches the nanotube. Another cause for this negative-positive phase response might be the structure of the tube itself, since the wall of the nanotube could cause the negative part while the silver in the middle could cause the positive part. In order to investigate this effect further the amplitude of the negative part of the phase signal as a function of the inverted scan rate was plotted (FIG. 14C). An exponential function has been fitted to the data and the mean lifetime for some of the silver filled peptide nanotubes has been plotted as a function of their height (FIG. 14d). FIG. 14c therefore suggests that the initial dip in the phase is due to the insulating-conducting structure of the nanotube. As the AFM tip approaches the silver-filled peptide nanotube, a capacitor is formed by the AFM tip and the silver inside the nanotube, with the wall of the nanotube acting as the dielectric. Due to the applied voltage (the AFM tip on the one side and a potential on the silver due to the capacitor formed by the backgate and the silver) this capacitor is charging while the AFM tip scans the peptide nanotube with the dip size depending on the scan rate.

Twelve silver wires were scanned during the experiments with a topography height in the range of 30 to 80 nm. The lift phase for a pure silver wire is shown in FIG. 15a, and the line profile illustrated by the gray line in FIG. 15A is shown in FIG. 15B. The phase shift follows relatively well the topography, as expected for a solid and conducting material [Staii et al., 2004]. As the silver wires are made from the peptide nanotube shell their topography height tends to be smaller compared to the peptide structures. The typical phase signals for the silver wires are of the same amplitude as the peptide nanotubes making the ratio between the height of the sample and the phase shift a possible way to distinguish between the two types of samples. This is in line with Equations 3 and 4 since silver has a high dielectric constant while the peptide is an insulating material.

### Example 3

This example describes experiments performed according to some embodiments of the present invention for electrochemical characterization of four types of 8-amino acid peptide nanofibers, referred to below as NS, NC, CN and CS. The amino acid sequence of each type of nanofibers is listed in Table 3, below.

TABLE 3

| | |
|---|---|
| NS | H₂N-Asn-Ser-Gly-Ala-Ile-Thr-Ile-Gly-CONH₂ |
| | (SEQ ID NO: 1) |
| NC | H₂N-Asn-Cys-Gly-Ala-Ile-Thr-Ile-Gly-CONH₂ |
| | (SEQ ID NO: 2) |
| CN | H₂N-Cys-Asn-Gly-Ala-Ile-Thr-Ile-Gly-CONH₂ |
| | (SEQ ID NO: 3) |
| CS | H₂N-Cys-Ser-Gly-Ala-Ile-Thr-Ile-Gly-CONH₂ |
| | (SEQ ID NO: 4) |

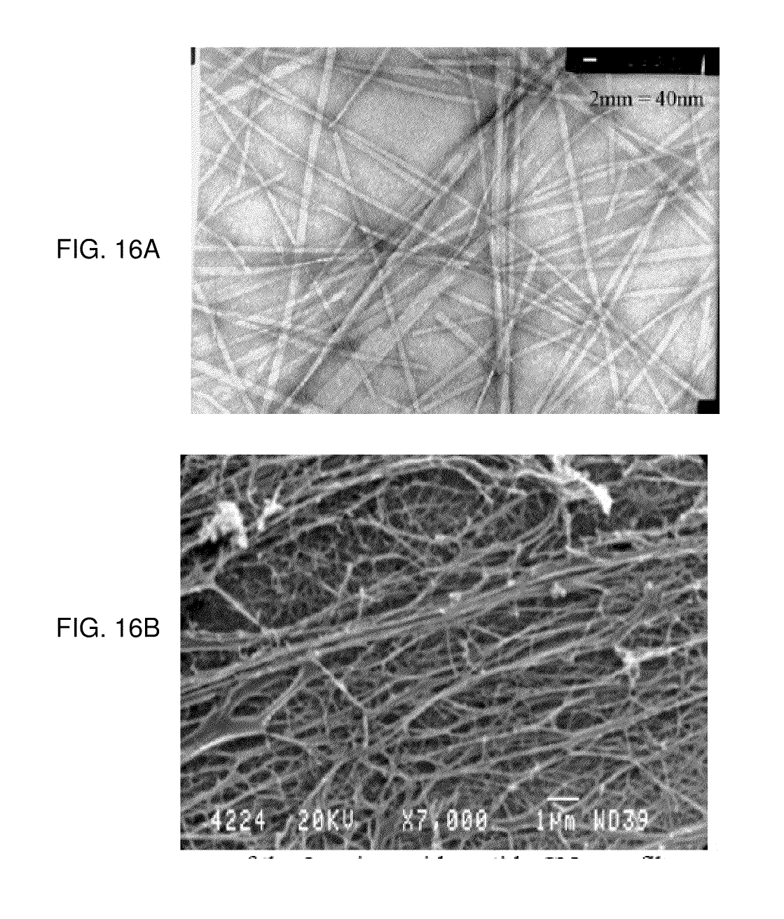

The nanofibers are formed by dissolving different amounts of the peptide powder in distilled water at room temperature. Samples are incubated at room temperature during 4 days to get a higher density of nanofibers. As representative examples, SEM images of the NC and CN nanofibers are shown in FIGS. 16A-B, respectively.

Nanofibers and gold modified nanofibers were evaluated by cyclic voltammetry (CV) on different working electrodes, graphite, gold and platinum. The screen printed working electrodes were acquired from Eco Bio Services (graphite electrodes) and from BVT Technologies (gold and platinum electrodes).

For the CV experiments a 10 mM K3Fe[CN]₆ in phosphate buffer pH 7.0 was prepared. Nanofibers samples were prepared and were immobilized on top of the working electrodes by physical adsorption at room temperature. A pseudo Ag/AgCl reference electrode was used on all the experiments.

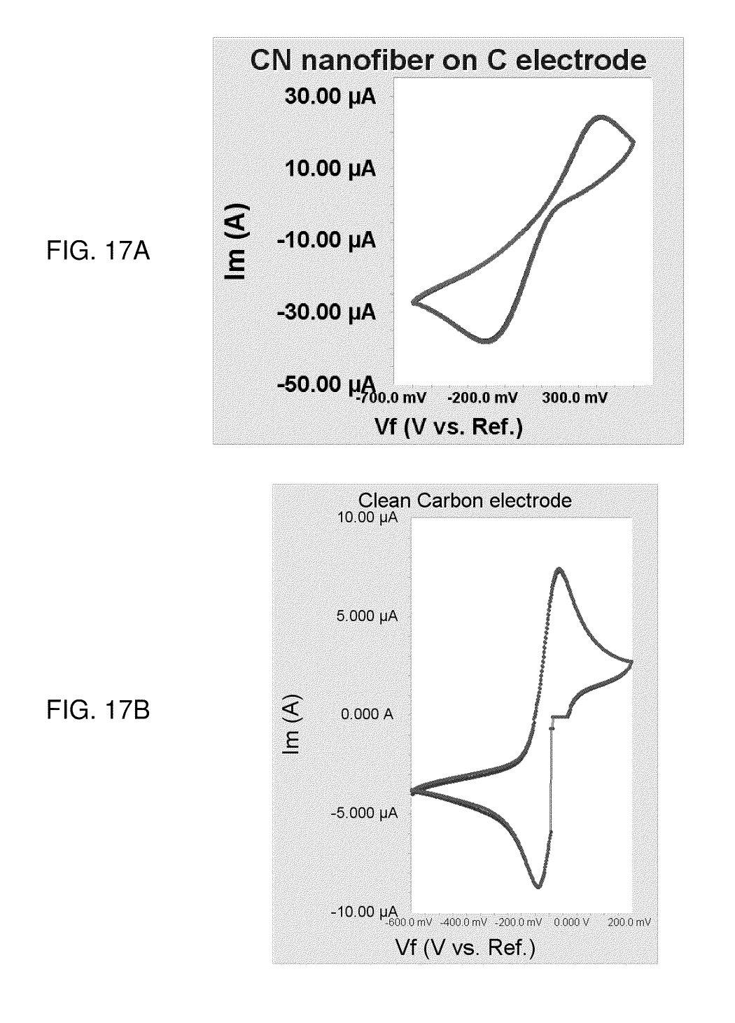

The results showed on FIGS. 17A and 17B, demonstrate that the presence of the CN peptide nanofibers increase the current about 3 times when compared with a clean graphite electrode (no nanotubes deposited).

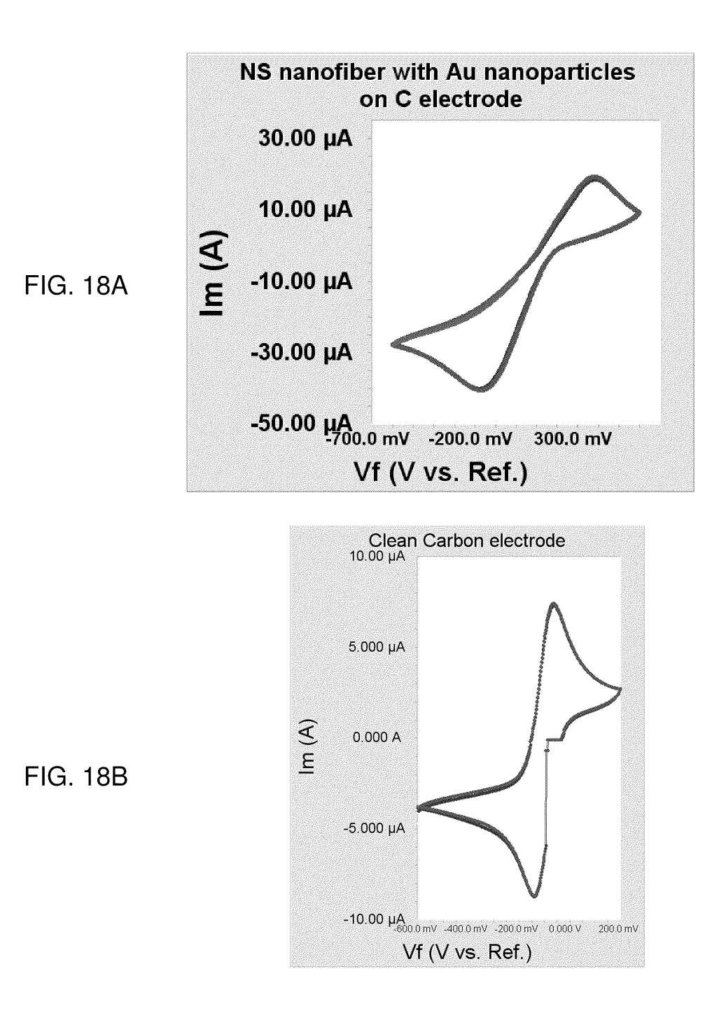

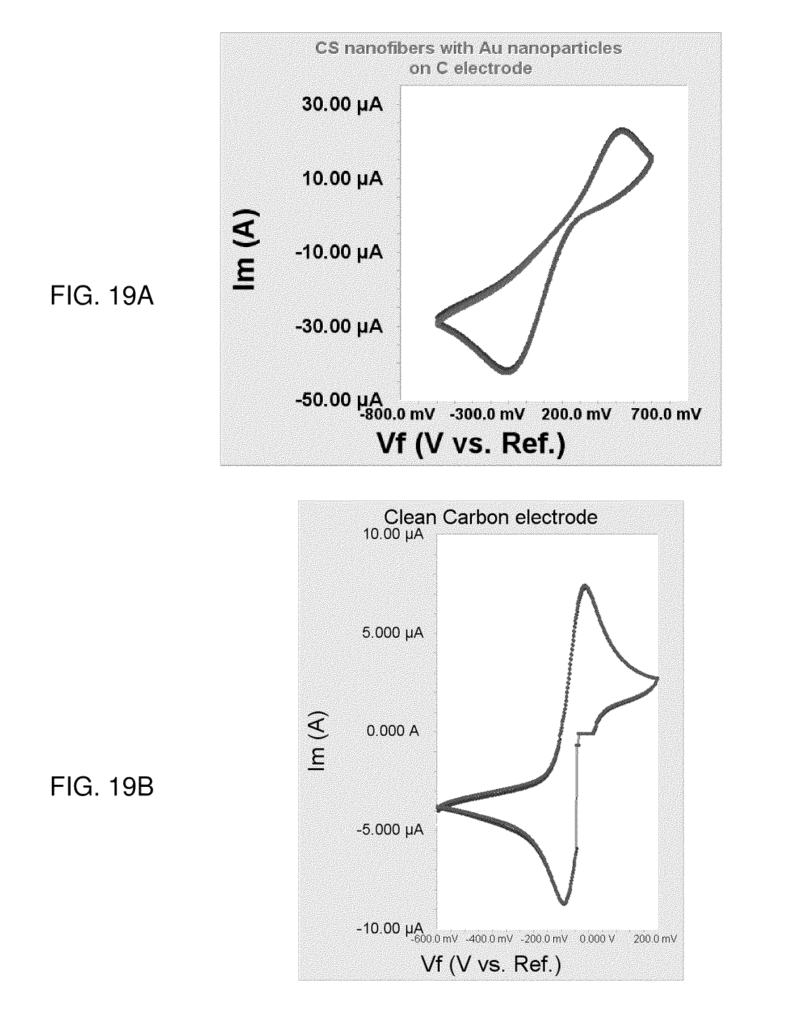

The sensitivity of the graphite electrodes modified with CN and NS nanofibers modified with gold nanoparticles, as shown in FIGS. 18A-B and 19A-B, respectively, was enhanced by the presence of these nanofibers on the surface of the electrode. The electrode surface is increasing by the presence of the nanofibers which explains the increase in the current.

The results obtained demonstrate that the nanostructures of the present embodiments are suitable for use in biosensing devices, which can be manufactured in accordance with some embodiments of the present invention.

### REFERENCES

[1] Chun, A., Morales, J., Webster, T., Fenniri, H., in: Vo-Dinh, T. (Ed.), Nanotechnology in Biology and Medicine. Methods, Devices and Applications, CRC Press, Boca Raton 2007, pp. 1-2.
[2] Boncheva, M., Whitesides, G. M., MRS Bull. 2005, 30, 736-742.
[3] Whitesides, G. M., Mathias, J. P., Seto, C. T., Science 1991, 254, 1312-1319.
[4] Praveena, G., Kolandaivel, P., Santhanamoorthi, N., Renugopalakrishnan, V., Ramakrishna, S., J. Nanosci. Nanotechnol. 2007, 7, 2253-2259.
[5] Banta, S., Megeed, Z., Casali, M., Rege, K., Yarmush, M. L., J. Nanosci. Nanotechnol. 2007, 7, 387-401.
[6] Colombo, G., Soto, P., Gazit, E., Trends Biotechnol. 2007, 25, 211-218.
[7] Hirst, A. R., Huang, B. Q., Castelletto, V., Hamley, I. W., Smith, D. K., Chem. Eur. J. 2007, 13, 2180-2188.
[8] MacPhee, C., Woolfson, D., Curr. Opin. Solid State. Mater. Sci. 2004, 8, 141-149.
[9] Raman, S., Machaidze, G., Lustig, A., Aebi, U., Burkhard, P., Nanomedicine 2006, 2, 95-102.
[10] Ghadiri, M. R., Granja, J. R., Buehler, L. K., Nature 1994, 369, 301-304.
[11] Ghadiri, M. R., Granja, J. R., Milligan, R. A., McRee, D. E., Khazanovich, N., Nature 1993, 324-327.
[12] Buriak, J. M., Ghadiri, M. R., Mater. Sci. Eng. C Biomim. Supramol Syst. 1997, 4, 207-212.
[13] Gao, X. Y., Matsui, H., Adv. Mater. 2005, 17, 2037-2050.
[14] Gazit, E., Chem. Soc. Rev. 2007, 36, 1263-1269.
[15] Scheibel, T., Curr. Opin. Biotechnol. 2005, 16, 427-433.
[16] Tsai, C. J., Zheng, J., Aleman, C., Nussinov, R., Trends Biotechnol. 2006, 24, 449-454.
[17] Zhang, S. G., Nat. Biotechnol. 2003, 21, 1171-1178.
[18] Zhang, S. G., Marini, D. M., Hwang, W., Santoso, S., Curr. Opin. Chem. Biol. 2002, 6, 865-871.
[19] Gorbitz, C. H., Chem. Commun. 2006, 2332-2334.
[20] Reches, M., Gazit, E., Science 2003, 300, 625-627.
[21] Gazit, E., Plenty of Room for Biology at the Bottom: an Introduction to Bionanotechnology, Imperial College Press, London 2007.
[22] Adler-Abramovich, L., Reches, M., Sedman, V. L., Allen, S. et al., Langmuir 2006, 22, 1313-1320.
[23] Kol, N., Adler-Abramovich, L., Barlam, D., Shneck, R. Z. et al., Nano Lett. 2005, 5, 1343-1346.
[24] Yeh, J., Lazareck, A., Kim, J., Xu, J., Du, S., Biosens. Bioelectron. 2007, 23, 568-574.
[25] Yemini, M., Reches, M., Gazit, E., Rishpon, J., Anal. Chem. 2005, 77, 5155-5159.
[26] Yemini, M., Reches, M., Rishpon, J., Gazit, E., Nano Lett. 2005, 5, 183-186.
[27] Scheibel, T., Parthasarathy, R., Sawicki, G., Lin, X. M. et al., Proc. Natl. Acad. Sci. USA 2003, 100, 4527-4532.
[28] Lieber, C. M., Wang, Z. L., MRS Bull. 2007, 32, 99-108.
[29] Patolsky, F., Lieber, C., Mater. Today 2005, 8, 20-28.
[30] Patolsky, F., Timko, B. P., Zheng, G. F., Lieber, C. M., MRS Bull. 2007, 32, 142-149.
[31] Reches, M., Gazit, E., Phys. Biol. 2006, 3, S10-S19.
[32] Dimaki, M., Boggild, P., Nanotechnology 2005, 16, 759-763.
[33] Hughes, M., Nanoelectromechanics in Engineering and Biology, CRC Press, Boca Raton 2003.
[34] Chen, D. F., Du, H., Li, W. H., Sens. Actuat. A Phys. 2007, 133, 329-334.
[35] Jung, J. Y., Kwak, H. Y., Anal. Chem. 2007, 79, 5087-5092.
[36] Li, Y. L., Dalton, C., Crabtree, H. J., Nilsson, G., Kaler, K., Lab Chip 2007, 7, 239-248.
[37] Tuukkanen, S., Kuzyk, A., Toppari, J. J., Hakkinen, H. et al., Nanotechnology 2007, 18.
[38] Yang, M., Zhang, X., Sens. Actuat. A Phys. 2007, 135, 73-79.
[39] Dimaki, M., and Boggild, P. Frequency dependence of the structure and electrical behaviour of carbon nanotube networks assembled by dielectrophoresis. Nanotechnology 2005, 16, 759-763
[40] Tjernberg, J. et al. Arrets of β-Amyloid fibril formation by a pentapeptide ligand. J. Biol. Chem. 15, (1996), 8545-8548.
[41] Borkrath, M. et al. Scanned conductance microscopy of carbon nanotubes and λ-DNA. Nano Letters. 2, (2002), 187-190
[42] Zhou, Y. et al. Fabrication and electrical characterization of polyaniline-based nanofibers diameter below 30 nm. Applied Phys. Letters. 83, (2003), 3800-3802
[43] Staii, C. et al. Quantitative analysis of scanning conductance microscopy, Nano Letters. 4, (2004), 859-862
[44] Jespersen, T. et al. Charge trapping in carbon nanotube loops demonstrated by electrostatic force microscopy, Nano Letters. 5, (2005), 1838-1841
[45] Colchero, J. et al. Resolution enhancement and improved data interpretation in electrostatic force microscopy. Physical Rev. 64, (2001), 245203-1-11
[46] Song, Y. et al. Synthesis of peptide-nanotube platinum-nanoparticle composites. Chem. Comm. (2004), 1044-1045
[47] Yemini, M. et al. Peptide nanotube-modified electrodes for enzyme-biosensor applications. Anal. Chem. 77, (2005), 5155-5159
[48] Yemini, M. et al. Novel electrochemical biosensing platform using-self-assembled peptide nanotubes. Nano Letters. 5, (2005), 183-186

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A method of manipulating an organic nanostructure, comprising:
contacting a liquid sample having the organic nanostructure therein with an arrangement of electrodes; and
applying voltage to said arrangement of electrodes to manipulate and immobilize said organic nanostructure over said electrodes by electrokinetics.

2. The method of claim 1, further comprising removing said liquid following said manipulation.

3. The method of claim 1, wherein said removing said liquid comprises directing a stream of gas.

4. The method of claim 1, wherein said voltage is alternating voltage.

5. The method of claim 4, wherein said a characteristic frequency of said alternating voltage is from about 0.5 MHz to about 1.5 MHz.

6. The method of claim 1, wherein said applying said voltage is for a time period of at least 2 minutes.

7. The method of claim 1, wherein said voltage is selected such that the nanostructure is immobilized to bridge a gap between two electrodes.

8. The method of claim 1, wherein said liquid sample comprises a plurality of organic nanostructure therein, and wherein a concentration of said organic nanostructures in said liquid is selected such that a single organic nanostructure is immobilized to bridge a gap between two electrodes.

9. The method of claim 1, wherein said liquid comprises a plurality of organic nanostructures therein, and wherein a concentration of said organic nanostructures in said liquid is selected such that a bundle of organic nanostructures is immobilized to bridge a gap between two electrodes.

10. The method of claim 1, wherein said liquid comprises a plurality of organic nanostructures therein, wherein said arrangement of electrodes forms a printed circuit board having a plurality of inter-electrode gaps, and wherein said voltage is selected such that at least two different nanostructures are immobilized to bridge respective two gaps.

11. The method of claim 10, further comprising cutting said printed circuit board to form at least two electronic devices each having at least two gapped electrodes and at least one immobilized nanostructure bridging said gap.

12. The method of claim 1, wherein the nanostructure is an elongated nanostructure.

13. The method of claim 1, wherein the nanostructure is a peptide nanostructure.

14. The method of claim 13, wherein said peptide nanostructure is selected from the group consisting of a peptide nanotube and a peptide nanowire.

15. The method of claim 1, said manipulation is by dieletrophoresis.

16. The method of claim 1, wherein said manipulation is by eletrophoresis.

17. An electronic assembly, comprising a plurality of electronic devices formed on a single substrate, each electronic device having at least two gapped electrodes and at least one immobilized peptide nanostructure bridging said gap.

18. The electronic assembly of claim 17, wherein said electronic devices are laterally separated and independently operative.

19. The electronic assembly of claim 17, wherein said electronic devices are identical.

20. The electronic assembly of claim 17, wherein at least one of said electronic devices is a field-effect transistor, and where said gap is between a source electrode and a drain electrode of said field-effect transistor.


SEQUENCE LISTING (4 sequences)

SEQ ID NO: 1 - protein, 8 aa, Artificial sequence
  Peptide nanofiber
NSGAITIG

SEQ ID NO: 2 - protein, 8 aa, Artificial sequence
  Peptide nanofiber
NCGAITIG

SEQ ID NO: 3 - protein, 8 aa, Artificial sequence
  Peptide nanofiber
CNGAITIG

SEQ ID NO: 4 - protein, 8 aa, Artificial sequence
  Peptide nanofiber
CSGAITIG